(19) United States
(12) Patent Application Publication
(10) Pub. No.: US 2012/0108048 A1
(43) Pub. Date: May 3, 2012

(54) THREE-DIMENSIONAL SEMICONDUCTOR DEVICES AND METHODS OF FABRICATING THE SAME

(75) Inventors: Jong Heun Lim, Seoul (KR); Jae Joo Shim, Suwon-si (KR); Hyo Jung Kim, Seoul (KR); Kyung Hyun Kim, Seoul (KR); Chang Sup Mun, Suwon-si (KR)

(73) Assignee: SAMSUNG ELECTRONICS CO., LTD., Suwon-Si (KR)

(21) Appl. No.: 13/286,384

(22) Filed: Nov. 1, 2011

(30) Foreign Application Priority Data
Nov. 1, 2010 (KR) 10-2010-0107827

(51) Int. Cl. H01L 21/28

(52) U.S. Cl. 438/586; 438/585; 257/E21.19

(57) ABSTRACT

A method of fabricating a three-dimensional semiconductor memory device includes providing a substrate which includes a cell array region and a peripheral region. The method further includes a peripheral structure on the peripheral region of the substrate, where the peripheral structure includes peripheral circuits and is configured to expose the cell array region of the substrate. The method further includes forming a lower cell structure on the cell array region of the substrate, forming an insulating layer to cover the peripheral structure and the lower cell structure on the substrate, planarizing the insulating layer using top surfaces of the peripheral structure and the lower cell structure as a planarization stop layer, and forming an upper cell structure on the lower cell structure.

### CROSS-REFERENCE TO RELATED APPLICATIONS

A claim of priority under 35 U.S.C. §119 is made to Korean Patent Application No. 10-2010-0107827, filed on Nov. 1, 2010, in the Korean Intellectual Property Office, the entire contents of which are hereby incorporated by reference.

### BACKGROUND

Embodiments of the inventive concepts relate generally to a semiconductor device and a method of fabricating the same, and more particularly, to three-dimensional semiconductor memory devices and methods of fabricating the same.

The continued development of highly integrated semiconductor devices is spurred in part by consumer demand for low-cost, superior performance products. Indeed, particularly in the case of semiconductor devices, increased device integration is a major factor in achieving price points satisfying market demands. Conventionally, semiconductor memory devices include planar or two-dimensional (2D) memory cell arrays, i.e., memory cell arrays having memory cells laid-out in a two-dimensional plane. Further integration of such devices is becoming more difficult (and costly) as patterning technologies approach practical limits. At the very least, prohibitively expensive process equipment would be needed to achieve major advances in 2D memory cell array device integration.

As a result, three-dimensional (3D) semiconductor memory devices have been proposed in which the memory cells of the memory cell array are arranged in three dimensions. However, there are significant manufacturing obstacles in achieving low-cost, mass-production of 3D semiconductor memory devices, particularly in the mass-fabrication of 3D devices that maintain or exceed the operational reliability of their 2D counterparts.

### SUMMARY

According to example embodiments of the inventive concepts, a method of fabricating a three-dimensional semiconductor memory device is provided which includes providing a substrate comprising a cell array region and a peripheral region, forming a peripheral structure on the peripheral region of the substrate, the peripheral structure comprising peripheral circuits and configured to expose the cell array region of the substrate, forming a lower cell structure on the cell array region of the substrate, forming an insulating layer to cover the peripheral structure and the lower cell structure on the substrate, planarizing the insulating layer using top surfaces of the peripheral structure and the lower cell structure as a planarization stop layer, and forming an upper cell structure on the lower cell structure.

According to other example embodiments of the inventive concepts, a method of fabricating a three-dimensional (3D) semiconductor memory device is provided which includes forming a peripheral circuit structure on a peripheral circuit region of a substrate, forming a 3D memory cell array on a cell array region of the substrate, and forming an interconnection structure between the 3D memory cell array and the peripheral circuit structure. The forming of the 3D memory cell array includes forming a lower cell structure on the cell array region of the substrate, the lower cell structure spaced from the peripheral circuit structure, forming an insulating layer to cover the substrate, the peripheral structure and the lower cell structure, planarizing the insulating layer using top surfaces of the peripheral circuit structure and the lower cell structure as a planarization stop layer such that a portion of the insulating layer remains on the substrate between the lower cell structure and the peripheral circuit structure, and forming an upper cell structure on the lower cell structure.

According to still other example embodiments of the inventive concepts, a three-dimensional semiconductor memory device is provided which includes a substrate comprising a cell array region and a peripheral region, a peripheral structure comprising peripheral circuits and an insulating pattern to cover the peripheral circuits on the peripheral region, a cell structure comprising conductive layers and insulating layers stacked alternately and repeatedly on the cell array region, penetrating structures electrically connected to the substrate through the cell structure, and a spacer disposed on a sidewall of the peripheral structure adjacent to the cell array region, where the spacer comprises a plurality of layers formed of different materials.

### BRIEF DESCRIPTION OF THE DRAWINGS

The accompanying drawings are included to provide a further understanding of the inventive concepts, and are incorporated in and constitute a part of this specification. The drawings illustrate exemplary embodiments of the inventive concepts and, together with the description, serve to explain principles of the inventive concepts. In the drawings:

FIG. 1 is a schematic block diagram illustrating a three-dimensional semiconductor memory device according to some embodiments of the inventive concepts;

FIG. 2 is a schematic circuit diagram illustrating a cell array of a three-dimensional semiconductor memory device according to some embodiments of the inventive concepts;

FIG. 3 is a perspective view illustrating a cell array of a three-dimensional semiconductor memory device according to some embodiments of the inventive concepts;

FIG. 4 is a perspective view illustrating a cell array of a three-dimensional semiconductor memory device according to first embodiments of the inventive concepts;

FIGS. 5A through 5L are sectional views for reference in describing a method of fabricating the three-dimensional semiconductor memory device according to the first embodiments of the inventive concepts;

FIGS. 6A through 6G are sectional views for reference in describing a method of fabricating a three-dimensional semiconductor memory device according to the first embodiments of the inventive concepts;

FIGS. 7A through 7D are enlarged sectional views of a portion A of FIG. 6G;

FIGS. 8A through 8D are sectional views for reference in describing a method of fabricating a three-dimensional semiconductor memory device according to second embodiments of the inventive concepts;

FIG. 9 is a sectional view illustrating a three-dimensional semiconductor memory device according to third embodiments of the inventive concepts;

FIG. 10 is a schematic block diagram of a memory system including a nonvolatile memory device according to some embodiments of the inventive concepts;

FIG. 11 is a schematic block diagram of a memory card including a nonvolatile memory device according to embodiments of the inventive concepts; and

FIG. 12 is a schematic block diagram illustrating an example of an information processing system including a nonvolatile memory system according to some embodiments of the inventive concepts.

### DETAILED DESCRIPTION

Exemplary embodiments of the inventive concepts will be described below in more detail with reference to the accompanying drawings. The embodiments of the inventive concepts may, however, be embodied in different forms and should not be construed as limited to the embodiments set forth herein. Rather, these embodiments are provided so that this disclosure will be thorough and complete, and will fully convey the scope of the inventive concepts to those skilled in the art. Like reference numerals refer to like elements throughout the description.

It will also be understood herein that when a layer such as a conductive layer, a semiconductor layer or an insulating layer is referred to as being “on” another layer or substrate, the layer may be directly on the another layer or substrate, or intervening layers may also be present. It will also be understood that, although the terms such as a first, a second, a third, etc. may be used herein to describe layers or processes, the layers or processes should not be limited by these terms. These terms are only used to distinguish one layer or process from another layer or process.

All terms used herein are to describe the inventive concepts that should not be limited by these terms. As used herein, the singular forms are intended to include the plural forms as well, unless the context clearly indicates otherwise. It also will be understood that, as used herein, the term “comprises” and/or “comprising” is open-ended, and includes one or more stated constituents, steps, actions and/or elements without precluding one or more unstated constituents, steps, actions and/or elements.

Furthermore, embodiments in the detailed description will be described with sectional views and/or plan views as ideal exemplary views of the inventive concepts. In the drawings, the dimensions of layers and regions are exaggerated for clarity of illustration. Thus, the exemplary views may be modified according to manufacturing technology and/or allowable error. Therefore, the embodiments of the present invention are not limited to the specific shape illustrated in the exemplary views, but may include other shapes that may be created according to manufacturing processes. For example, an etched region described with right angles may be rounded or be configured with a predetermined curvature. Thus, the regions illustrated in figures are schematic, and shapes of the regions illustrated in figures exemplifies particular shapes of device regions, but do not limit the scope of the inventive concepts.

Hereinafter, exemplary embodiments of the inventive concepts will be described in detail with reference to the accompanying drawings.

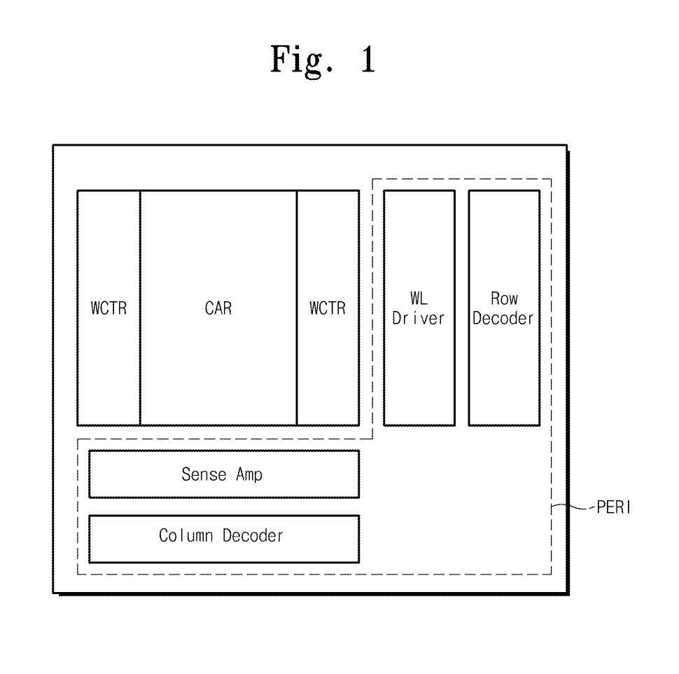

FIG. 1 is a schematic block diagram illustrating a three-dimensional semiconductor memory device according to some embodiments of the inventive concepts.

Referring to FIG. 1, the semiconductor memory device of this example includes a cell array region CAR, a contact region WCTR and a peripheral circuit region PERI.

In the cell array region CAR, memory cells are arranged in three-dimensions, and bit lines and word lines are electrically coupled to the memory cells. At least part of the contact region WCTR may be disposed between the cell array region CAR and the peripheral circuit region PERI, and contact plugs and interconnection lines may be disposed in the contact region WCTR to connect the memory cells with peripheral circuits. Peripheral circuits, which are configured to program or read data stored in the memory cells, may be formed in the peripheral circuit region PERI. For example, as shown in the example of FIG. 1, the peripheral circuits may include a word line (WL) driver, a sense amplifier (Amp), a row decoder, and a column decoder, and control circuitry (not shown).

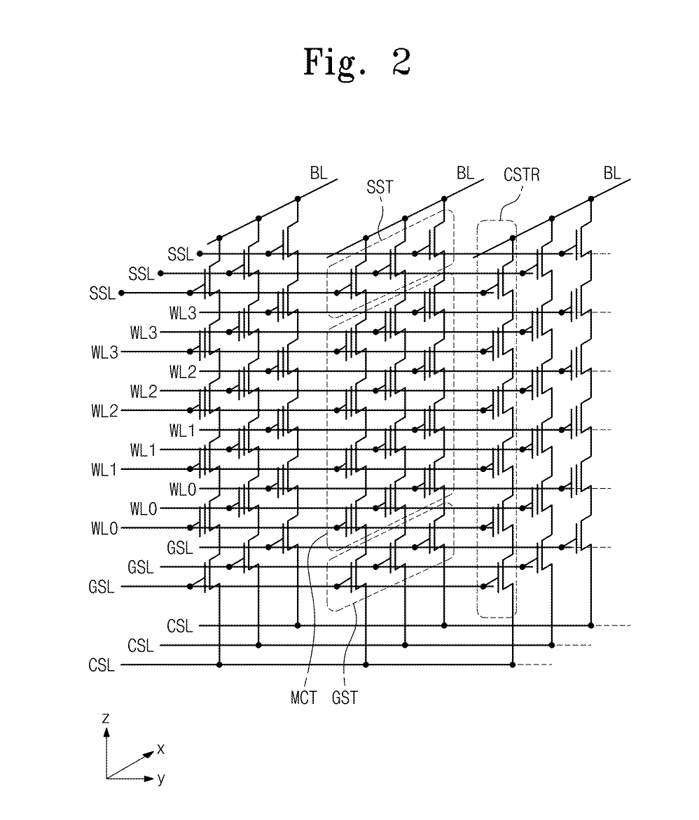

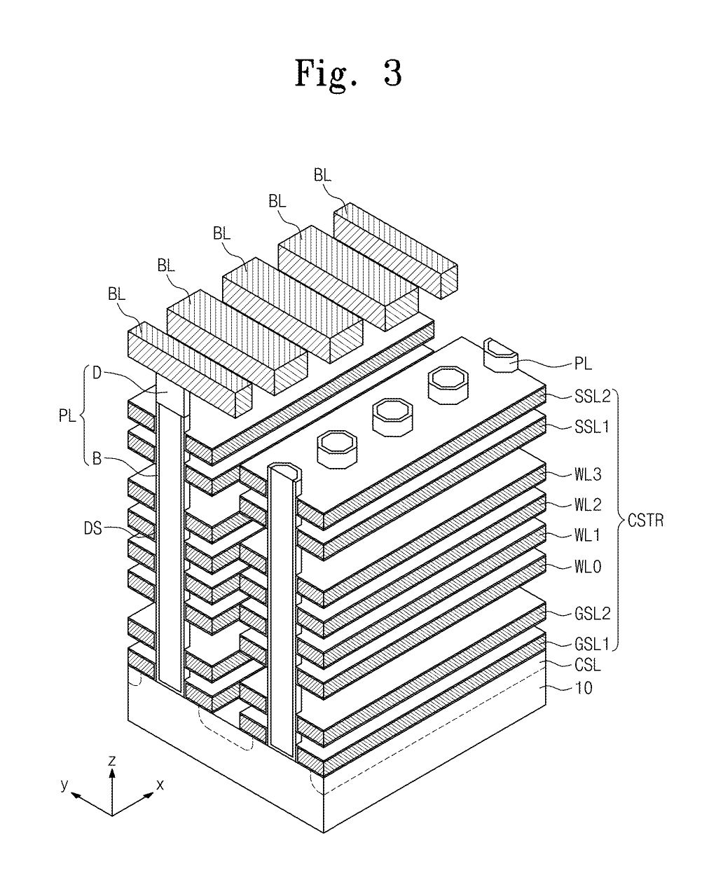

FIGS. 2 and 3 are a schematic circuit diagram and a perspective view, respectively, of a cell array of a three-dimensional semiconductor memory device according to some embodiments of the inventive concepts.

Referring to FIG. 2, in some embodiments of the inventive concepts, the cell array of the three-dimensional semiconductor memory device includes at least one common source line CSL, a plurality of bit lines BL and a plurality of cell strings CSTR interposed between the common source line CSL and the bit lines BL.

In this example, the bit lines BL physically extend parallel to each other in a two-dimensional plane, and a plurality of the cell strings CSTR are electrically connected in parallel to each of the bit lines BL. Each of cell strings CSTR is connected one or more common source lines CSL. That is, in the example of FIGS. 2 and 3, at least one common source line CSL physically extends perpendicular to the bit lines BL, whereby the bit lines BL and the at least one common source line CSL define intersection regions there between. The plurality of the cell strings CSTR are disposed at the respective intersection regions between each of the bit lines BL and the at least one common source line CSL. As such, in the case of a single common source line CSL, a plurality of cell strings CSTR extend parallel to each other and are commonly connected at a first end to the common source line CSL, and connected at a second end to a respective one of the bit lines BL. In the case of multiple common source lines CSL, multiple pluralities of cell strings CSTR extend parallel to each other that are commonly connected at the second end to a same one of the bit lines BL, and connected at the first end to a respective one of the common source lines CSL.

In the case where the cell array region CAR includes a plurality of common source lines CSL, they may be arranged in a two-dimensional plane as shown in the example of FIGS. 2 and 3. In this case, the common source lines CSL may be connected with one another in an equipotential state. Alternatively, the common source lines CSL may be electrically separated from one another such that they are controlled independently.

Each of the cell strings CSTR may include a ground selection transistor GST coupled to the common source line CSL, a string selection transistor SST coupled to the bit line BL, and a plurality of memory cell transistors MCT disposed between the ground and string selection transistors GST, SST. Here, the ground selection transistor GST, the memory cell transistors MCT and the string selection transistor SST may be connected in series.

Sources regions of the ground selection transistors GST may be connected in common to the common source line CSL. In addition, at least one ground selection line GSL, a plurality of word lines WL0 to WL3 and a plurality of string selection lines SSL, which serve as gate electrodes of the ground selection transistor GST, the memory cell transistors MCT and the string selection transistors SST, respectively, may be disposed between the common source line CSL and the bit lines BL. Moreover, each of the memory cell transistors MCT may include a data storage element.

Referring to the example of FIG. 3, the common source line CSL may provided as a conductive layer on a substrate 10 and/or provided as an impurity region in the substrate 10. The bit lines BL may be conductive patterns (e.g., metal lines) disposed over the substrate 10.

Each of the cell strings CSTR may include a plurality of ground selection lines GSL1 and GSL2 interposed between the common source line CSL and the bit lines BL, a plurality of word lines WL0 to WL3, and a plurality of string selection lines SSL and SSL2. In some embodiments, the string selection lines SSL1 and SSL2 may be used as the string selection line SSL of FIG. 2, and the ground selection lines GSL1 and GSL2 may be used as the ground selection line GSL of FIG. 2. Also, the ground selection lines GSL1 and GSL2, the word lines WL0 to WL3 and the string selection lines SSL1 and SSL2 may be conductive patterns stacked on the substrate 10.

Each of the cell strings CSTR may include a semiconductor pillar PL (or vertical semiconductor pattern), which may extend vertically from a common source line CSL and be connected to a bit line BL. The semiconductor pillar PL may penetrate the ground selection lines GSL1 and GSL2, the word lines WL0 to WL3 and the string selection lines SSL1 and SSL2. In other words, the semiconductor pillar PL may penetrate a plurality of conductive patterns stacked on the substrate 10. In addition, the semiconductor pillar PL may include a body portion B and at least one impurity region D. The impurity region D may be formed in one or two end portions of the semiconductor pillar PL; for example, a drain region, one of the impurity regions D, may be formed in a top portion of the semiconductor pillar PL (i.e., between the body portion B and the bit line BL).

A data storage layer DS may be disposed between the word lines WL0 to WL3 and the semiconductor pillars PL. According to some embodiments, the data storage layer DS may include a charge storing layer in which electrical charges can be stored. For example, the data storage layer DS may include one of a trap insulating layer, a floating gate electrode, or an insulating layer with conductive nanodots.

A dielectric layer serving as a gate dielectric layer of vertical transistor may be disposed between the ground selection lines GSL1 and GSL2 and the semiconductor pillar PL or between the string selection lines SSL1 and SSL2 and the semiconductor pillar PL. In certain embodiments, the dielectric layer is formed of the same material as the data storage layer DS. In other embodiments, the dielectric layer is formed of a material which is different from the data storage layer DS. For example, it may be formed of silicon oxide.

In the above-described example, the semiconductor pillar PL serves as a channel region of a metal-oxide-semiconductor field effect transistor (MOSFET), and the ground selection lines GSL1 and GSL2, the word lines WL0 to WL3, and the string selection lines SSL1 and SSL2 serves as gate electrodes of the MOSFETs. In detail, the word lines WL0 to WL3 may serve as gate electrodes of memory cell transistors, and the ground selection lines GSL1 and GSL2 and the string selection lines SSL1 and SSL2 may serve as gate electrodes of selection transistors. Here, the selection transistors may be, for example, configured to control an electrical connection between the bit line BL or the common source line CSL and the channel region of the memory cell transistor. In some aspects of the inventive concepts, the semiconductor pillar PL constitutes MOS capacitors along with the ground selection lines GSL1 and GSL2, the word lines WL0 to WL3 and the string selection lines SSL1 and SSL2.

In the meantime, energy band structures of the semiconductor pillars PL may be controlled by voltages applied to the ground selection lines GSL1 and GSL2, the word lines WL0 to WL3, and the string selection lines SSL1 and SSL2. For example, portions of the semiconductor pillars PL adjacent to the word lines WL0 to WL3 may become in an inversion state due to the voltages applied to the word lines WL0 to WL3. In addition, for example, other portions of the semiconductor pillars PL between the word lines WL0 to WL3 may also become in an inversion state due to a fringe field generated from the word lines WL0 to WL3. According to some embodiments, the word lines WL0 to WL3 and the selection lines SSL1 and SSL2 may be formed closely together so that a distance between two adjacent ones of these lines is shorter than half of a vertical width of an inversion region induced by the fringe field. In this case, depending on the voltages applied to the lines GSL1, GSL2, SSL1, SSL2, and WL0 to WL3, the inversion regions can vertically overlap each other, and the common source line CSL can be electrically connected to a selected bit line.

That is, the cell string CSTR may be configured such that the selection transistors (e.g., ground and string selection transistors including the lower and upper selection lines GSL1, GSL2, SSL1 and SSL2) and the memory cell transistors (e.g., MCT of FIG. 2) are electrically connected in series.

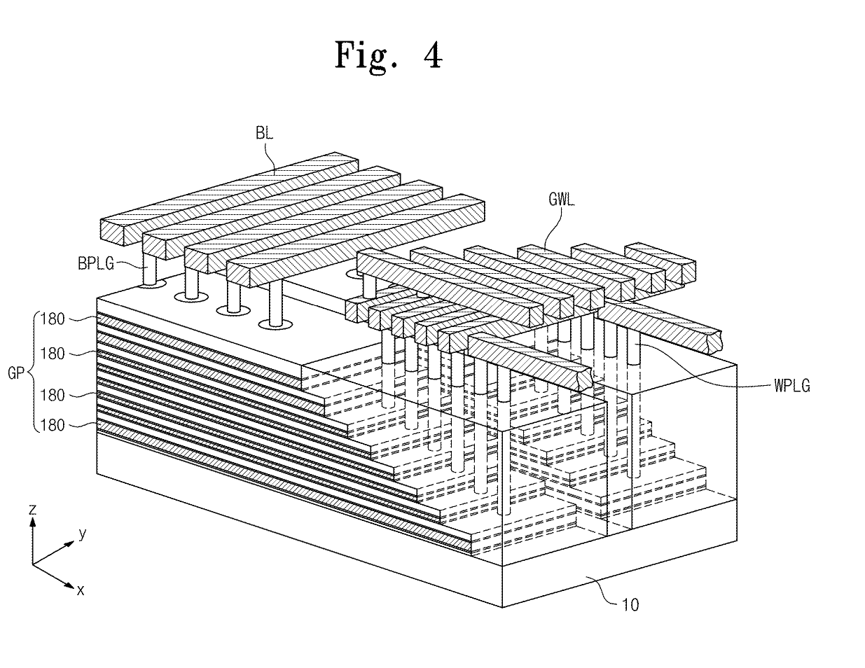

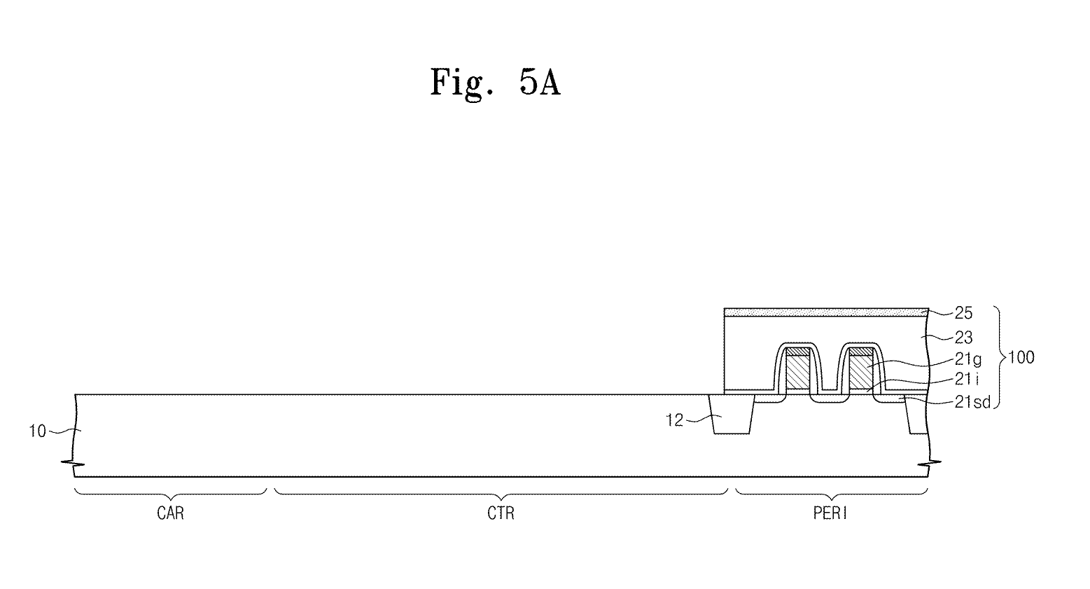

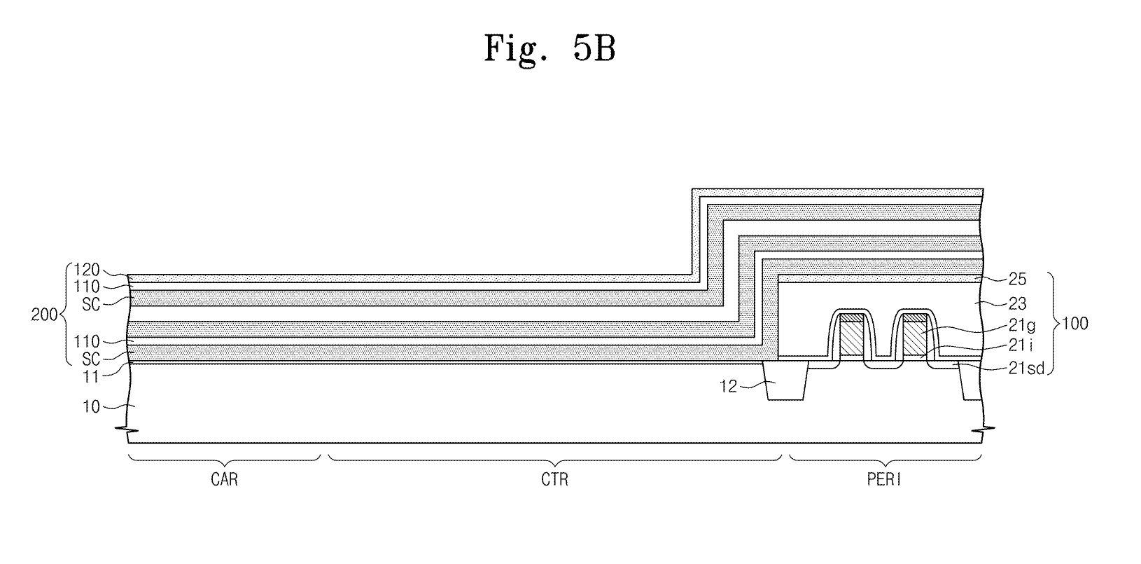

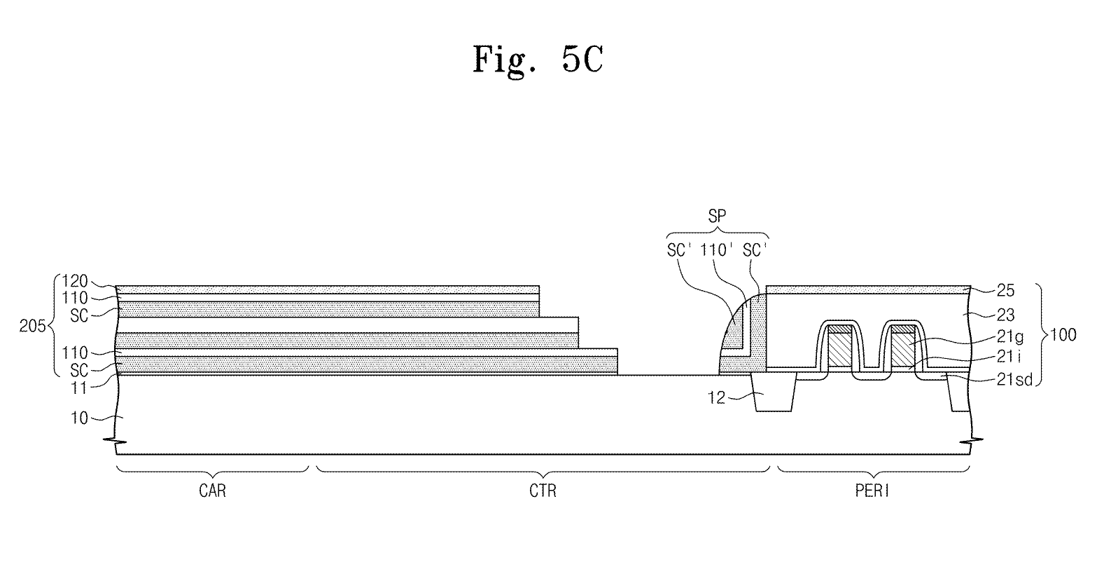

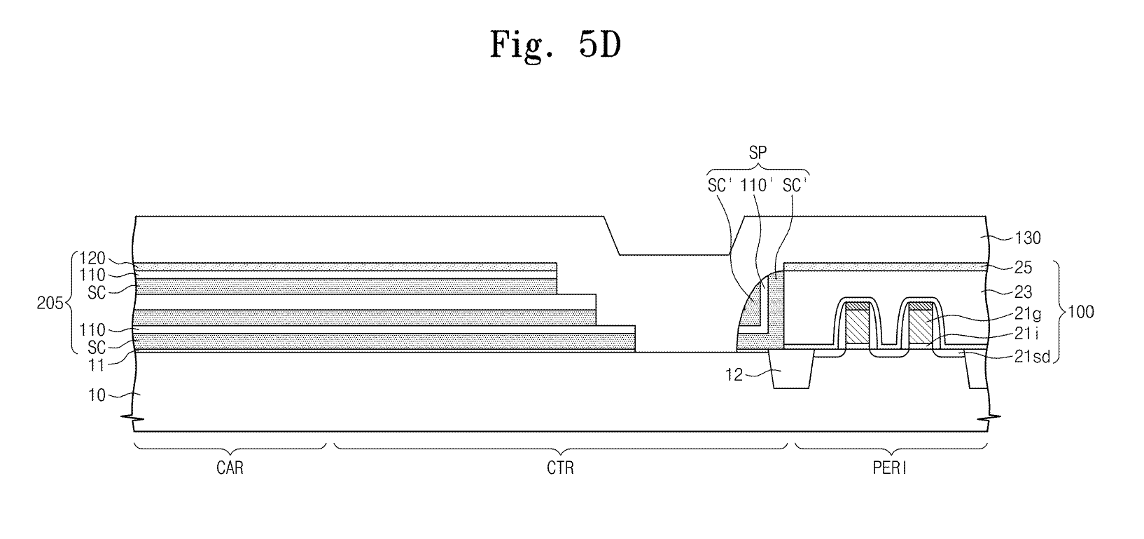

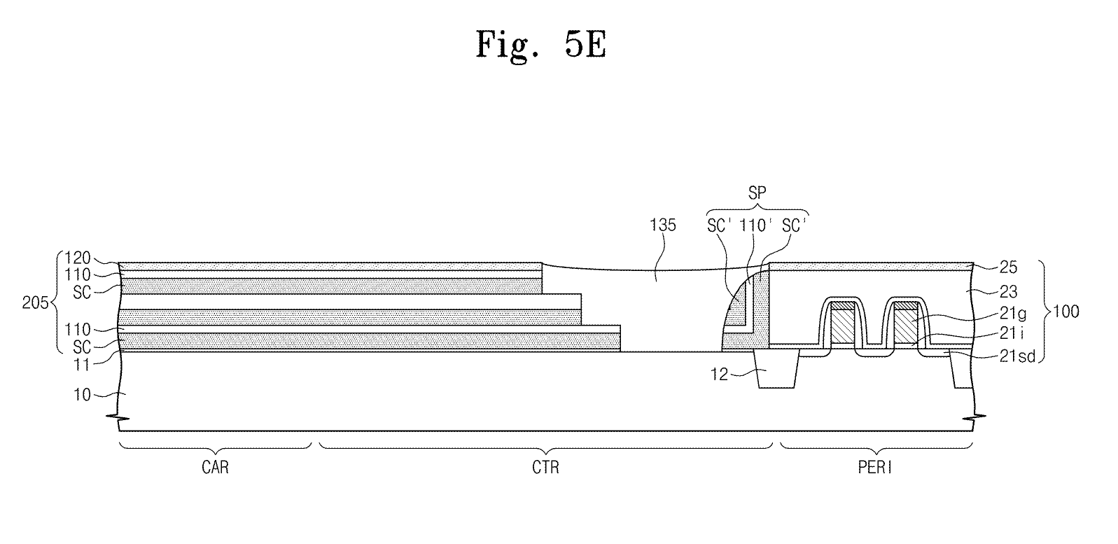

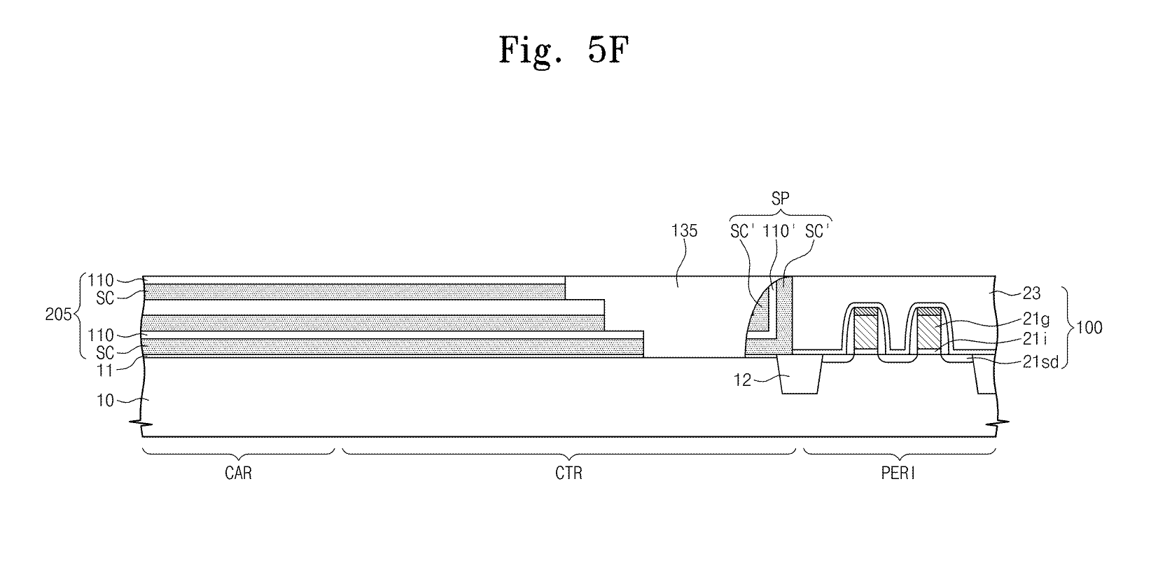

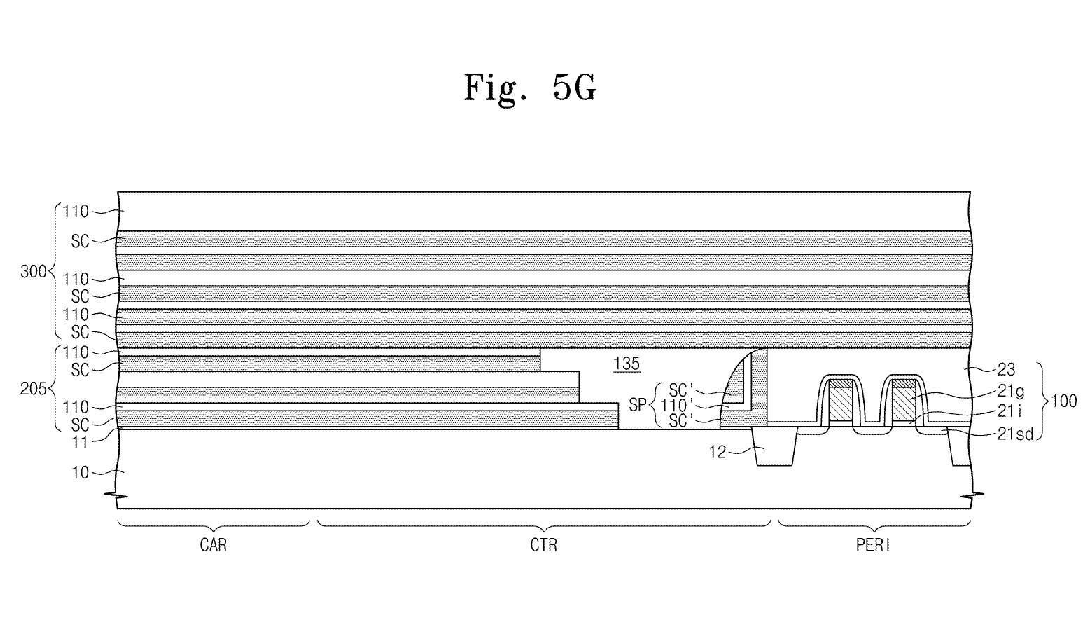

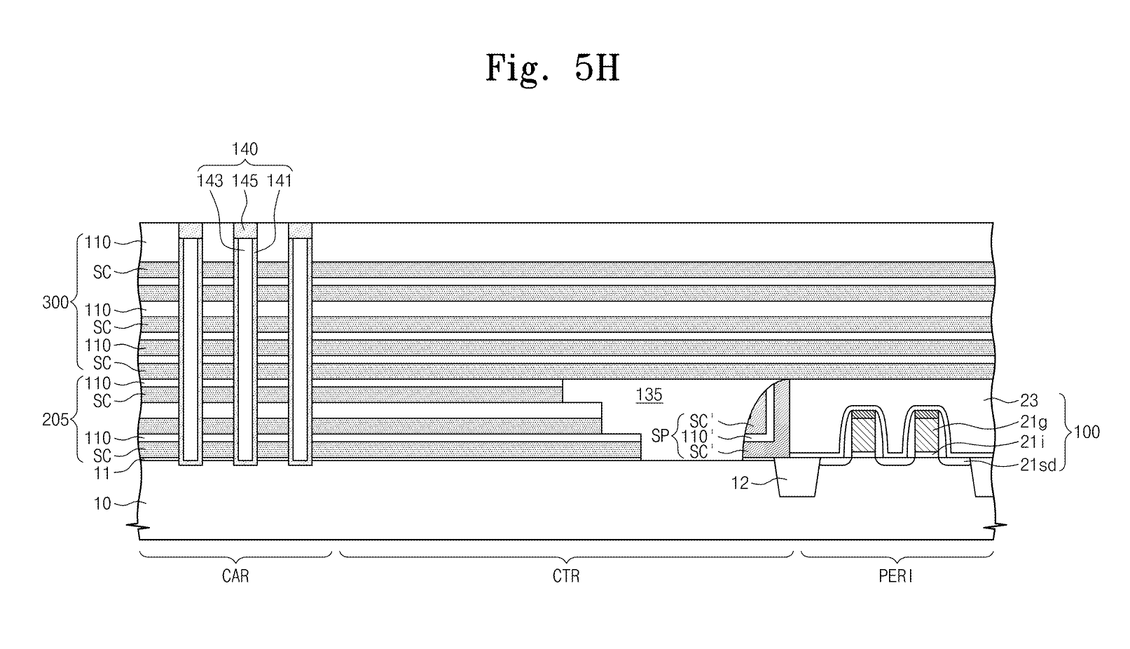

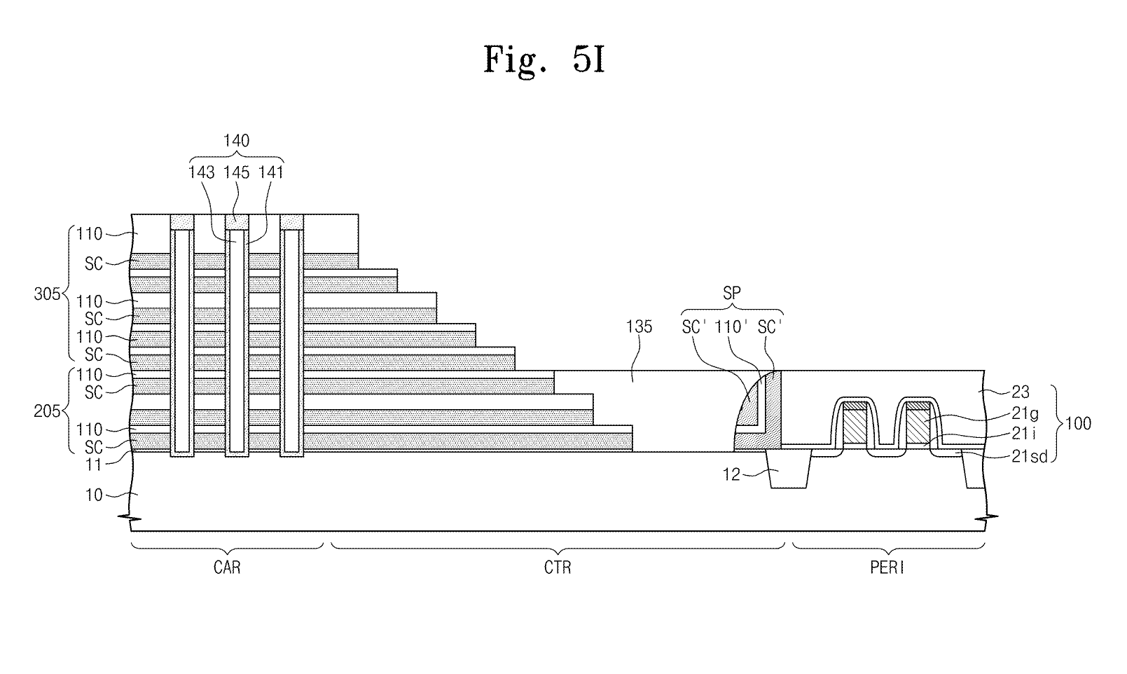

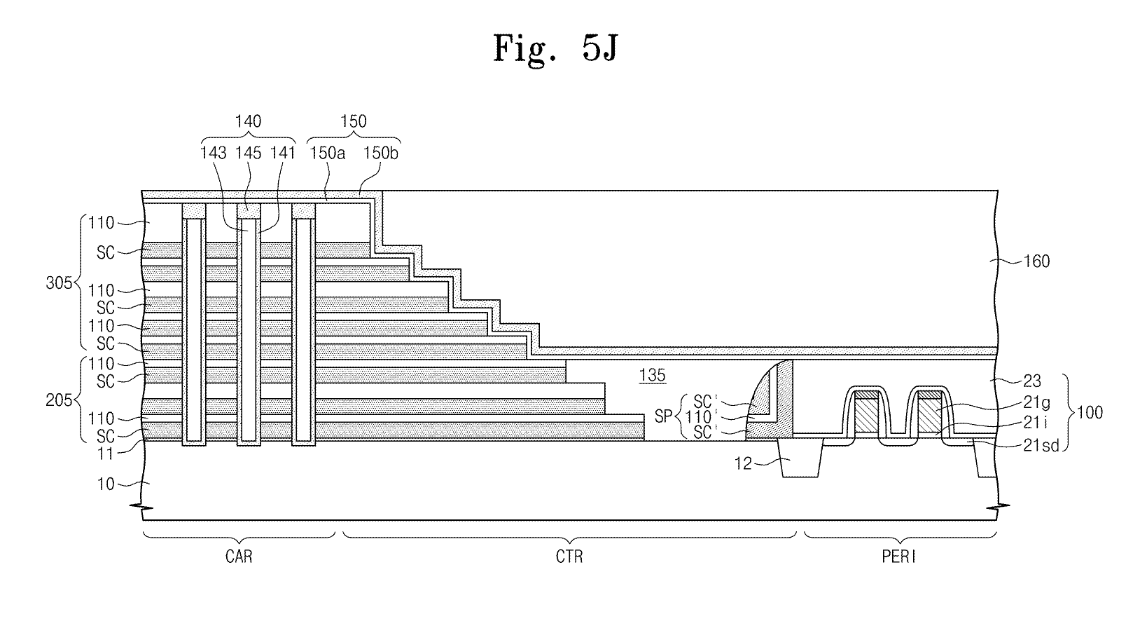

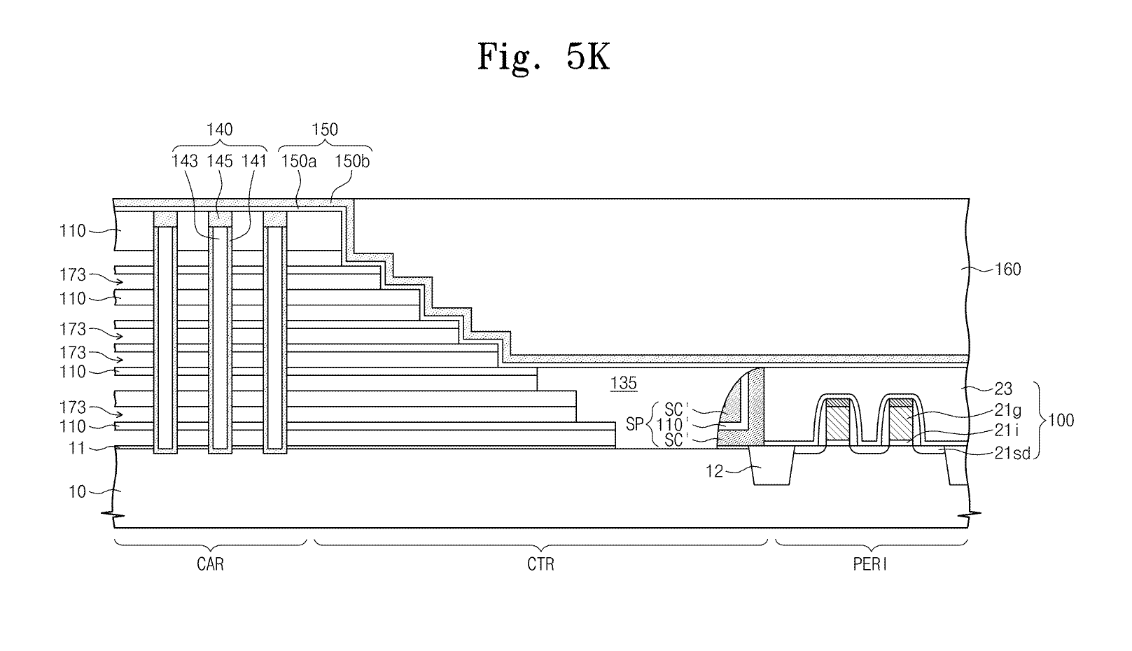

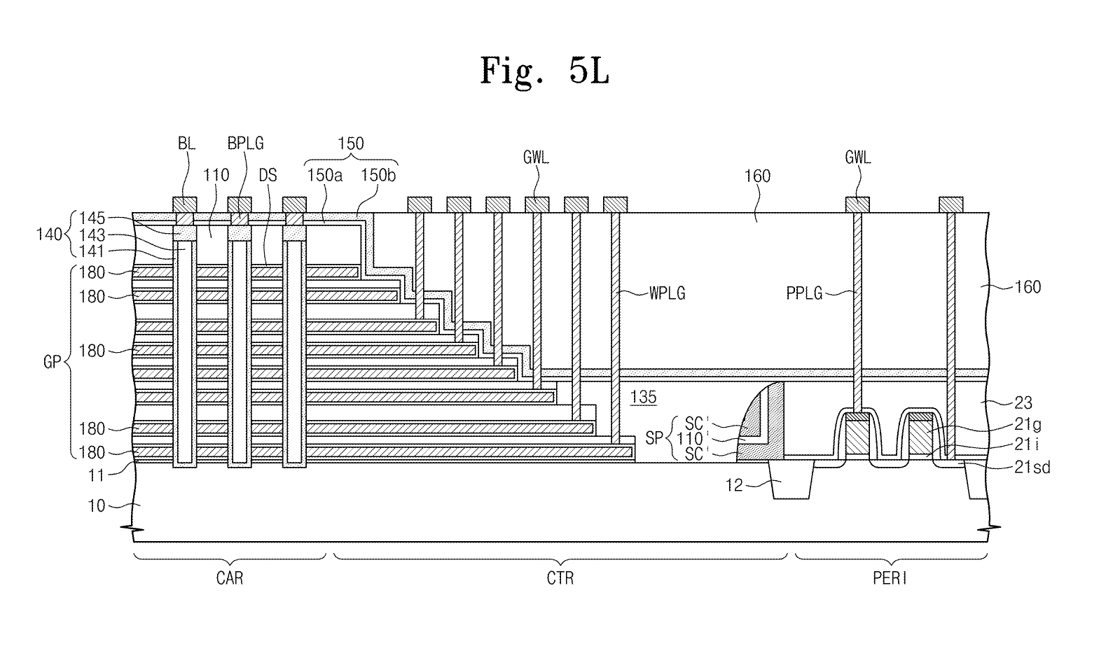

Hereinafter, methods of fabricating a three-dimensional semiconductor memory device according to first embodiments of the inventive concepts will be described in detail with reference to FIG. 4, FIGS. 5A through 5L, FIGS. 6A through 6G, and FIGS. 7A through 7D.

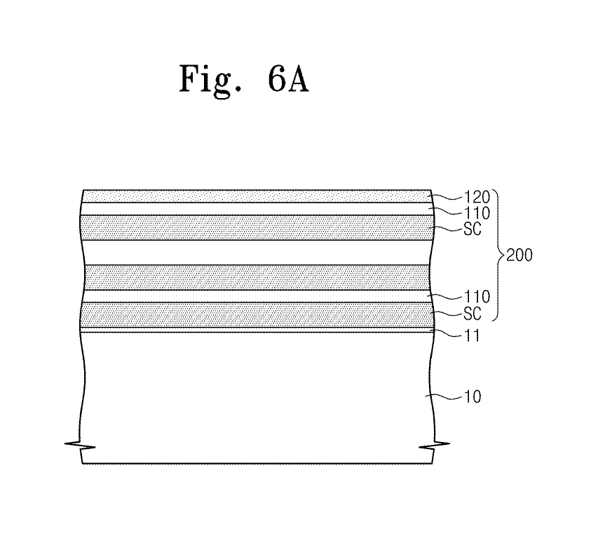

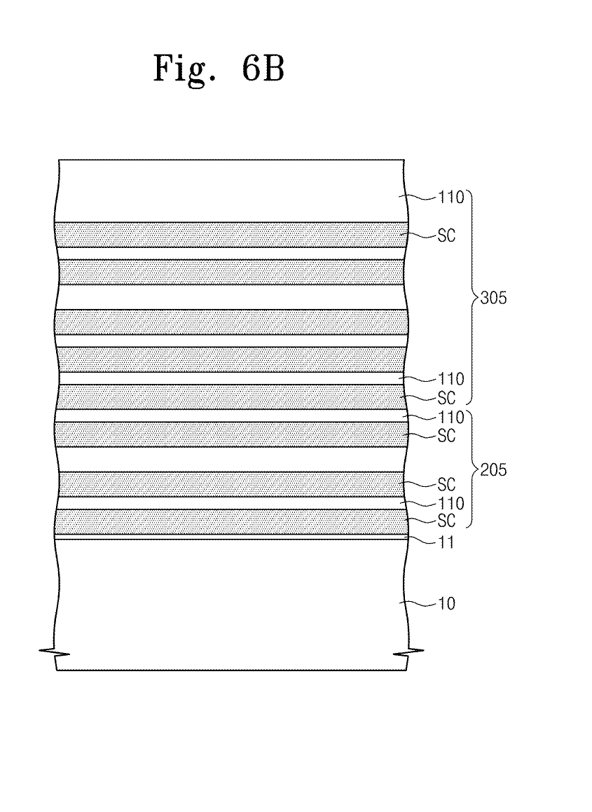

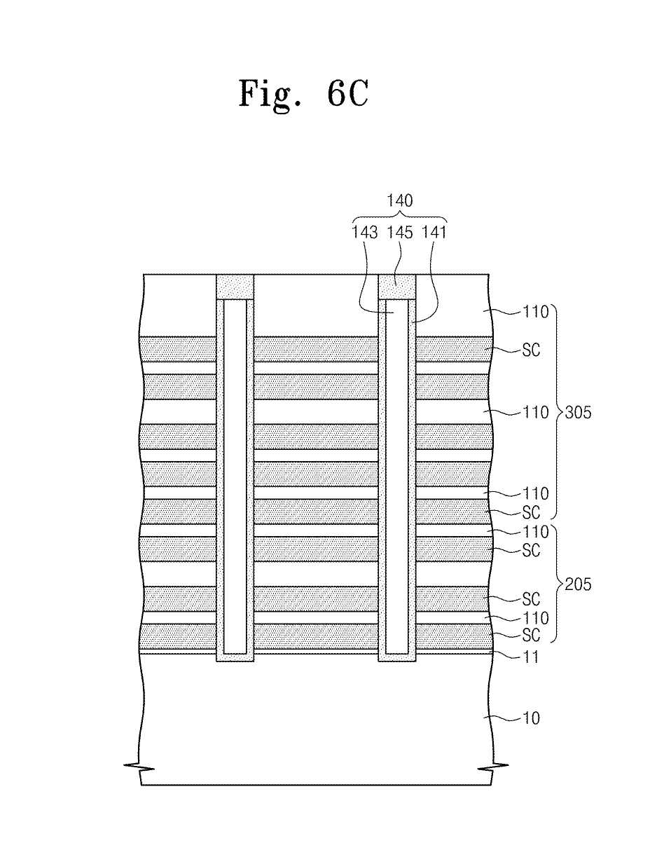

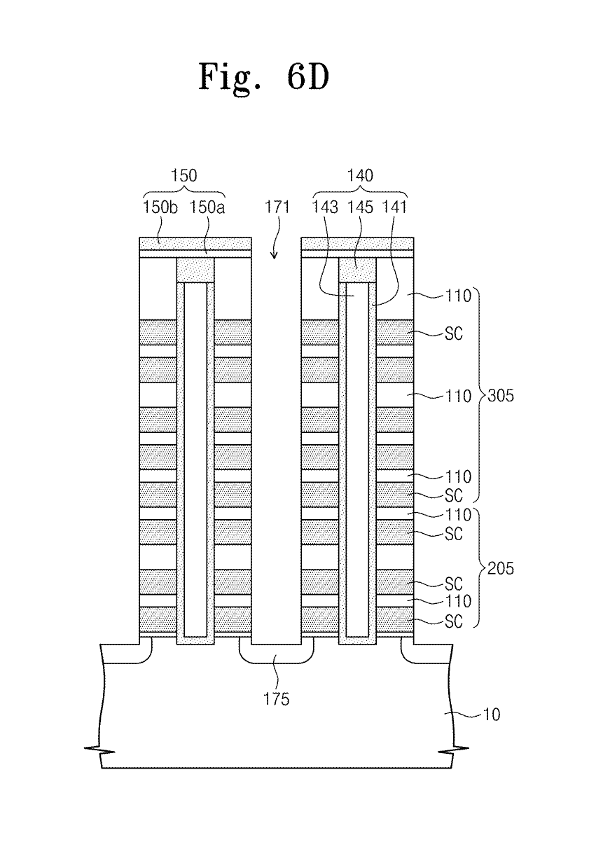

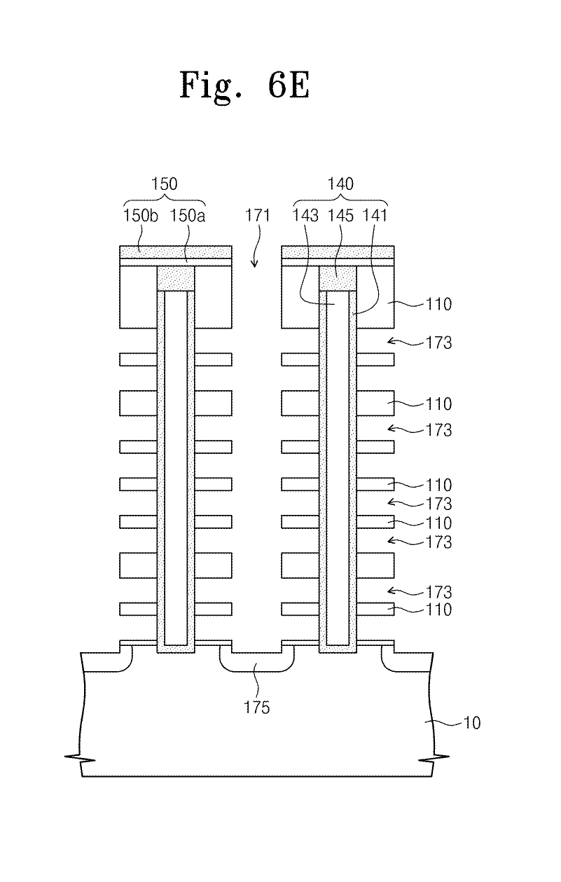

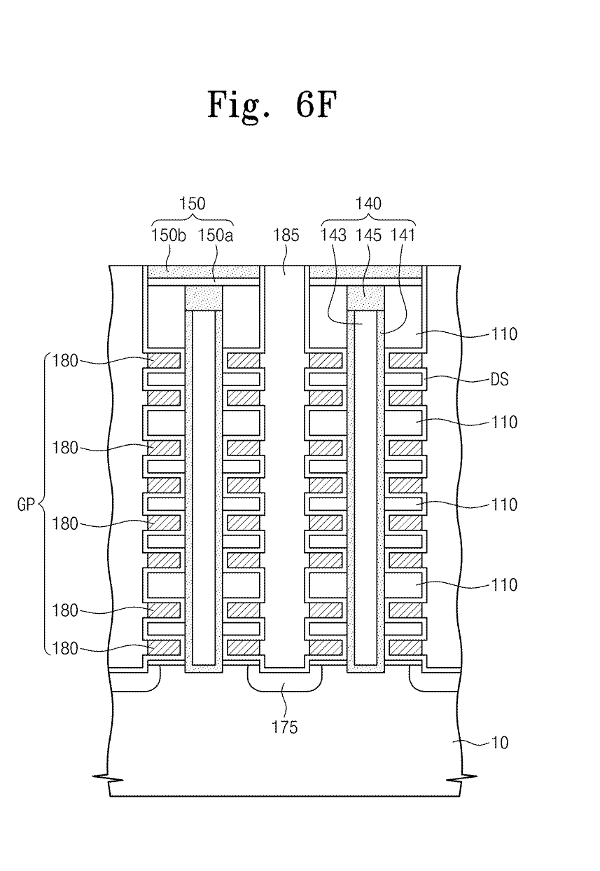

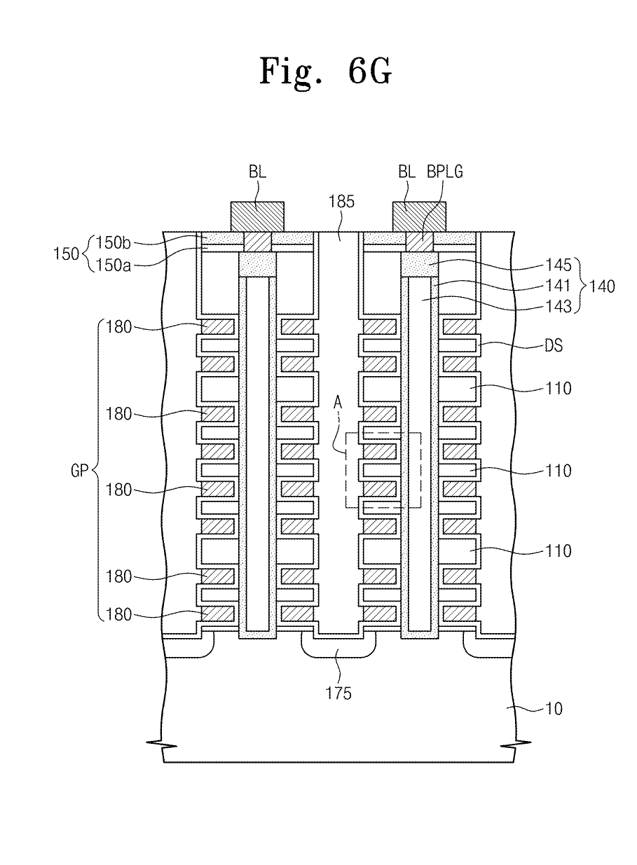

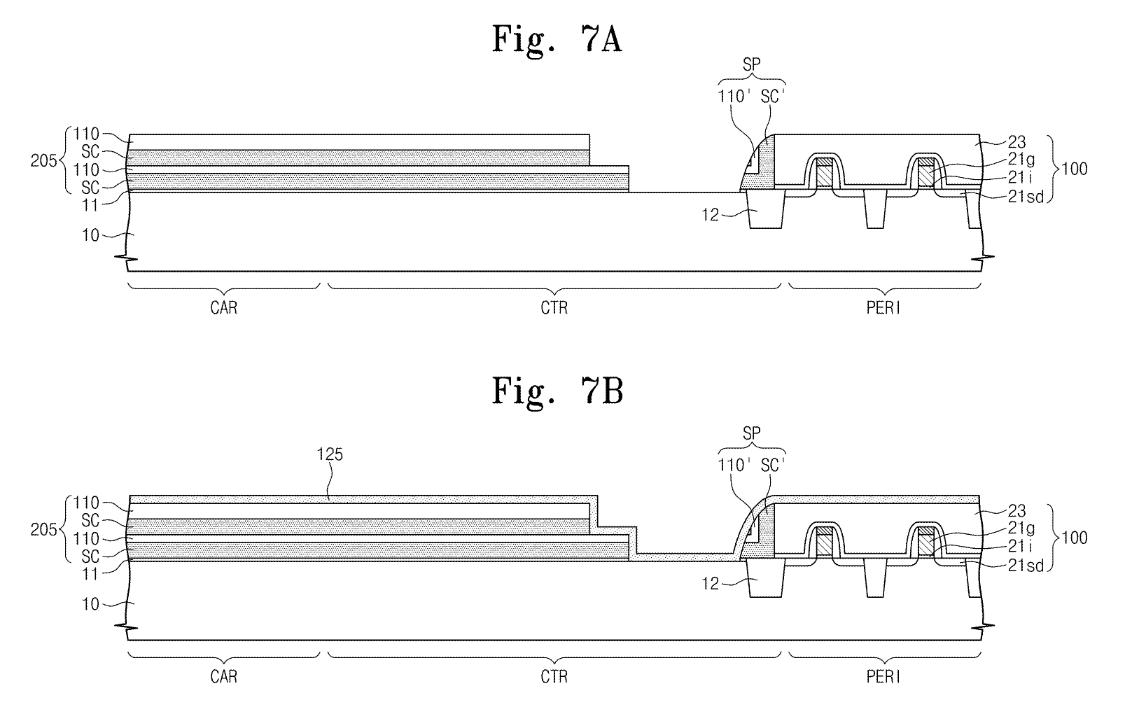

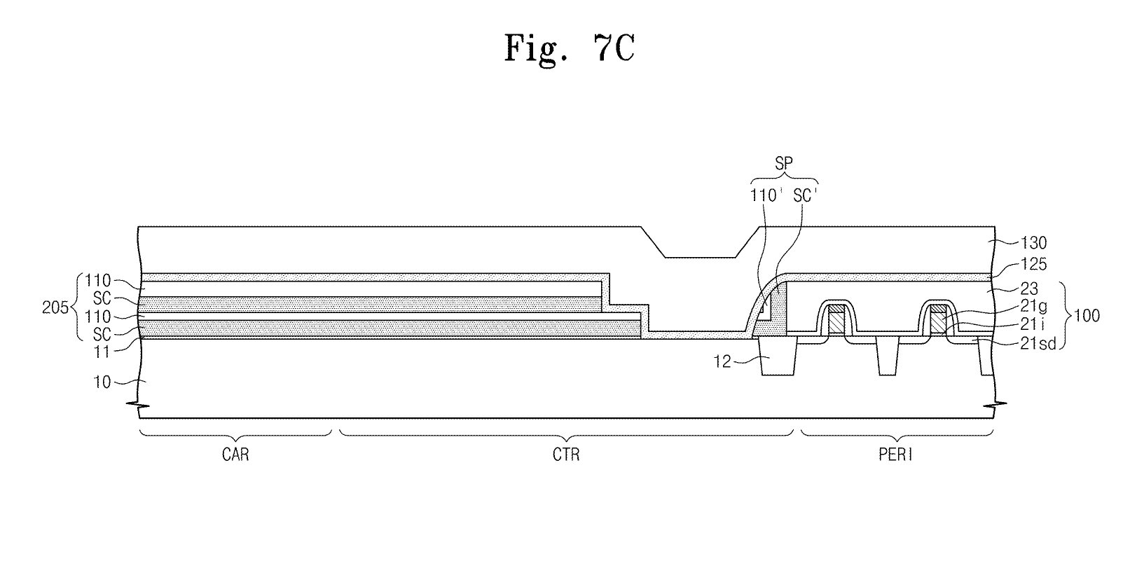

FIG. 4 is a perspective view illustrating a cell array of the three-dimensional semiconductor memory device according to first embodiments of the inventive concepts. FIGS. 5A through 5L and FIGS. 6A through 6G are sectional views illustrating a method of fabricating the three-dimensional semiconductor memory device of FIG. 4. Here, FIG. 5A through 5L show a portion of a cell array region CAR taken parallel to a xz plane of FIG. 4 and a portion of a peripheral circuit region PERI, and FIG. 6A through 6G show a portion of the cell array region CAR taken parallel to a yz plane of FIG. 4. FIGS. 7A through 7D are enlarged sectional views of a portion A of FIG. 6G.

Referring to FIG. 5A, a peripheral structure 100 including peripheral circuits may be formed on a peripheral circuit region PERI of a substrate 10.

The substrate 10 may be one of a semiconductor substrate (e.g., a silicon wafer), an insulating substrate (e.g., a glass), or a conductive or semiconductor substrate covered with an insulating material. For instance, the substrate 10 may be a silicon wafer having a first conductivity. The substrate 10 may include the cell array region CAR, the peripheral circuit region PERI and the contact region CTR, as described with reference to FIG. 1. Moreover, the substrate 10 may include active regions defined by isolation layers.

To form the peripheral structure 100, peripheral circuits may be formed on the peripheral circuit region PERI of the substrate 10, and a peripheral insulating layer 23 may be formed to cover the peripheral circuits. In some embodiments, a peripheral sacrificial layer 25 may be additionally formed to form the peripheral structure 100, as shown in FIG. 5A.

According to some embodiments, the formation of the peripheral circuits may include forming a word line driver, a sense amplifier, row and column decoders, and control circuits, which may be the same as those described with reference to FIG. 1. For example, as shown in FIG. 5A, peripheral transistors constituting the peripheral circuits may be formed on the peripheral circuit region PERI of the substrate 10. The peripheral transistors may be formed using the following process, which is presented as an example. A peripheral gate insulating layer and a peripheral gate layer may be sequentially stacked on the whole surface of the substrate 10. A peripheral gate pattern 21g and a peripheral gate insulating pattern 21i may be formed by patterning the peripheral gate insulating layer and the peripheral gate layer. Here, the peripheral gate pattern 21g may serve as gate electrodes of the peripheral transistors and be formed of doped polysilicon or a metallic material. Also, the peripheral gate insulating pattern 21i may be formed of silicon oxide using, for example, a thermal oxidation process. Subsequently, peripheral impurity regions 21sd may be formed in the substrate 10 on both sides of the peripheral gate patterns 21g and serve as source and drain electrodes of the peripheral transistors.

The formation of the peripheral insulating layer 23 may include depositing and planarizing an insulating material on the entire top surface of a resultant structure, in which the peripheral circuits are formed. The peripheral insulating layer 23 may be, for example, formed of silicon oxide. Here, a thickness of the peripheral insulating layer 23 may be determined in consideration of a vertical thickness of a lower layered structure 200, which will be subsequently formed on the cell array region CAR of the substrate 10.

The formation of the peripheral sacrificial layer 25 may include depositing an insulating material having an etch selectivity to the peripheral insulating layer 23 on the planarized peripheral insulating layer 23. The peripheral sacrificial layer 25 may be, for example, at least one of silicon, silicon oxide, silicon nitride, silicon oxynitride, silicon carbide, or silicon oxycarbide.

The peripheral insulating layer 23 and the peripheral sacrificial layer 25 may be patterned to expose the cell array region CAR and the contact region CTR of the substrate 10. In other words, even when the patterning is finished, the peripheral insulating layer 23 and the peripheral sacrificial layer 25 may remain locally or partially within the peripheral circuit region PERI on the substrate 10. That is, the peripheral structure 100 may be locally or partially formed on the peripheral circuit region PERI of the substrate 10 to expose the cell array region CAR and the contact region CTR of the substrate 10.

Referring to FIGS. 5B and 6A, a lower layered structure 200 may be formed on the substrate 10 on which the peripheral structure 100 is formed.

According to some embodiments, the lower layered structure 200 may be formed on the cell array region CAR and the contact region CTR of the substrate 10 and on the peripheral structure 100 of the peripheral circuit region PERI. In some embodiments, a thickness or height of the lower layered structure 200 may be substantially the same as a thickness or height of the peripheral structure 100. That is, the lower layered structure 200 may be formed to conformally and wholly cover the substrate 10 having the peripheral structure 100. Thus, a sidewall of peripheral structure 100 may be covered with the lower layered structure 200.

The lower layered structure 200 may include a plurality of insulating layers 110 and a plurality of sacrificial layers SC. The insulating layers 110 and the sacrificial layers SC may be alternately and repeatedly stacked using deposition processes as shown in FIGS. 5B and 6A. Each of the numbers of the insulating layers 110 and the sacrificial layers SC included in the lower layered structure 200 may be smaller than half the number of the conductive patterns (i.e., the word lines of FIG. 2), which will be vertically stacked in the cell array region CAR. In addition, a vertical thickness of each of the insulating layers 110 and the sacrificial layers SC may be less than a vertical thickness or height of the peripheral structure 100, and moreover it may be less than a vertical thickness of the peripheral gate pattern 21g. Here, a vertical thickness of an object may be interpreted as a length of the object measured along a direction perpendicular to a top surface of the substrate 10.

The insulating layers 110 and the sacrificial layers SC may be formed of materials having an etch selectivity with respect to each other in a subsequent wet etching process. For instance, the insulating layers 110 may be formed of at least one of silicon oxide and silicon nitride, and the sacrificial layers SC may be at least one selected from silicon, silicon oxide, silicon carbide and silicon nitride, which may be different from the insulating layer 110. In some embodiments, the insulating layers 110 may be formed of silicon oxide, and the insulating layers 110 may further include at least one high-k dielectric materials capable of contributing to formation of an inversion region as explained with reference to FIG. 3. Here, the high-k dielectric materials may be a dielectric material having a greater dielectric constant than silicon oxide. For example, the high-k dielectric materials may be silicon nitride, silicon oxynitride, or metal oxides.

According to example embodiments of the inventive concepts, a channel length of the memory cell transistor (e.g., MCT of FIG. 2) may depend on a thickness of the sacrificial layers SC in the lower layered structure 200. Meanwhile, when the sacrificial layers SC are formed using deposition processes as described above, the resulting channel length can be more precisely controlled when compared to the case where the channel length is determined using a patterning technique. Also, a space between the sacrificial layers SC (i.e., a thickness of the insulating layers 110) may be less than the maximum vertical length of the inversion region in a semiconductor pattern to be formed subsequently or in the semiconductor pillar PL.

Moreover, in some embodiments, the lower layered structure 200 may include a cell sacrificial layer 120 disposed at an uppermost level thereof. The cell sacrificial layer 120 may be formed of the same material and to the same thickness as the peripheral sacrificial layer 25.

The cell sacrificial layer 120 may be formed of an insulating material having an etch selectivity to the insulating layer 110 and/or the sacrificial layer SC. For example, the cell sacrificial layer 120 may be formed of at least one of silicon, silicon oxide, silicon nitride, silicon oxynitride, silicon carbide, or silicon oxycarbide. In some embodiments, the cell sacrificial layer 120 may be formed on the insulating layer 110 formed of silicon oxide, and in this case the cell sacrificial layer 120 may be formed of silicon nitride. In other some embodiments, the cell sacrificial layer 120 may be formed on the sacrificial layer SC formed of silicon nitride, and in this case, the cell sacrificial layer 120 may be formed of silicon oxide.

Meanwhile, before forming the lower layered structure 200, a lower gate insulating layer 11 may be further formed on a top surface of the substrate 10 exposed by the peripheral structure 100. In some embodiments, the lower gate insulating layer 11 may be formed by a thermal oxidation process.

Referring to FIG. 5C, the lower layered structure 200 may be patterned to form a lower cell structure 205 on the cell array region CAR of the substrate 10.

The lower cell structure 205 may have a contact portion of stepwise shape, which is extended from the cell array region CAR to the contact region CTR. For example, by patterning repeatedly a portion of the lower layered structure 200 on the contact region CTR, the lower cell structure 205 may have a stepwise structure. Since the lower cell structure 205 has the stepwise contact portion, conductive patterns, which will be formed on the cell array region CAR, can be electrically connected to the peripheral circuits in a simple manner.

According to some embodiments, to form the stepwise contact portion, the lower layered structure 200 may be patterned several times. For example, the patterning of the lower layered structure 200 may include alternate steps of reducing an area occupied by a mask pattern (not shown) and etching the lower layered structure 200.

The reduction of the area of the mask pattern may be performed to enlarge an area exposed by the mask pattern (i.e., the area of a region to be etched). Meanwhile, as the number of times the alternate processes are repeated increases, a width and thickness of the mask pattern may decrease.

A manner of etching the lower layered structure 200 may vary depending on the number of stacked sacrificial layers SC. For example, an etched amount of the lower layered structure 200 may decrease with a reduction in the area of the mask pattern. As the result of repeated etching of the lower layered structure 200, the insulating layers 110 may have edge portions with exposed top surfaces. That is, each of top surfaces of the insulating layers 110 constituting the lower cell structure 205 may be partially exposed in the contact region CTR. In other embodiments, each of top surfaces of the sacrificial layers SC, not the top surfaces of the insulating layers 110, may be partially exposed in the contact region CTR.

As described above, since the lower cell structure 205 may be formed to have the stepwise structure, the edge portions of the insulating layers 110 and/or the sacrificial layers SC can be disposed on the contact region CTR. Also, the farther a distance from the insulating layers 110 and the sacrificial layers SC to the substrate 10 is, the smaller the area occupied by the insulating layers 110 and the sacrificial layers SC may be. In other words, as the sacrificial layers SC and the insulating layers 110 are vertically farther from the substrate 10, sidewalls of the sacrificial layers SC and the insulating layers 110 are laterally farther from the peripheral circuit region PERI. Accordingly, a difference in vertical thickness between the lower cell structure 205 and the peripheral structure 100 may be lower than a vertical thickness of the lower cell structure 205 or the peripheral structure 100. Furthermore, the lower cell structure 205 may have substantially the same vertical thickness or height as the peripheral structure 100.

Meanwhile, according to some embodiments, the substrate 10 may be partially exposed in the contact region CTR adjacent to the peripheral circuit region PERI during the patterning of the lower layered structure 200. In addition, during the patterning of the lower layered structure 200, the lower layered structure 200 may be removed from the peripheral circuit region PERI. That is, as the formation of the lower cell structure 205 is continued, the peripheral sacrificial layer 25 or the peripheral insulating layer 23 may gradually be more exposed in the peripheral circuit region PERI.

In certain embodiments, when the lower layered structure 200 is patterned to form the stepwise lower cell structure 205 in the contact region CTR, the lower layered structure 200 may partially remain on a sidewall of the peripheral insulating layer 23 near the contact region CTR.

More specifically, since the lower layered structure 200 may be conformally formed on the substrate 10 having the peripheral structure 100, a portion of the lower layered structure 200 may cover a sidewall of the peripheral insulating layer 23. During the etching processes for forming the lower cell structure 205, the portion of the lower layered structure 200 may not be etched to form a spacer SP, which remains on the sidewall of the peripheral insulating layer 23 near the contact region CTR. For example, each of the spacers SP may include a sacrificial pattern SC′ and an insulating pattern 110′, which are respectively originated from the sacrificial layers SC and the insulating layers 110 constituting the lower layered structure 200. The sacrificial pattern SC′ and the insulating pattern 110′ may have the same material and thickness as the lowermost sacrificial layer SC and the lowermost insulating layer 110, respectively, of the lower layered structure 200.

Referring to FIG. 5D, a lower insulating layer 130 may be formed to cover the peripheral structure 100 and the lower cell structure 205.

In more detail, the formation of the lower insulating layer 130 may include depositing an insulating material on the substrate 10 having the peripheral structure 100, the lower cell structure 205, and the spacer SP. For instance, the lower insulating layer 130 may be formed using a physical vapor deposition (PVD) method, a chemical vapor deposition (CVD) method, a sub-atmospheric CVD (SACVD) method, a low-pressure CVD (LPCVD) method, a plasma-enhanced CVD (PECVD) method, or a high-density plasma CVD (HDP CVD) method. If the lower insulating layer 130 is formed using one of these deposition methods, the lower insulating layer 130 may conformally cover the previous structure formed on the substrate 10.

According to some embodiments, the lower insulating layer 130 may be deposited to a greater vertical thickness than the peripheral structure 100 or the lower cell structure 205. Thus, the lower insulating layer 130 may fill a gap region between the peripheral structure 100 and the lower cell structure 205. In the meantime, there may be a height or step difference between the peripheral structure 100 and the substrate 10 and/or between the lower cell structure 205 and the substrate 10 before the formation of the lower insulating layer 130. In this case, the height difference may be transferred to the lower insulating layer 130. That is, a top surface of the lower insulating layer 130 may not be flat as shown in FIG. 5D.

The lower insulating layer 130 may be formed of one of materials that are selected to have an etch selectivity to the insulating layers 110 and/or the sacrificial layers SC during the removal of the sacrificial layers SC from the lower cell structure 205. The lower insulating layer 130 may be formed of, for example, at least one of high-density plasma (HDP) oxide, tetraethyl orthosilicate (TEOS), plasma-enhanced TEOS (PE-TEOS), O3-TEOS, undoped silicate glass (USG), phosphosilicate glass (PSG), borosilicate glass (BSG), borophosphosilicate glass (BPSG), fluoride silicate glass (FSG), spin on glass (SOG), tonen silazene (TOSZ), or any combination thereof. Alternatively, the lower insulating layer 130 may include at least one of silicon nitride, silicon oxynitride or low-k dielectrics.

Referring to FIG. 5E, the lower insulating layer 130 may be planarized to expose top surfaces of the peripheral structure 100 and the lower cell structure 205. That is, the peripheral structure 100 and the lower cell structure 205 may be used as a planarization stop layer during the planarization process.

In detail, according to some embodiments, the peripheral sacrificial layer 25 and the cell sacrificial layer 120 may be disposed as the uppermost layers of the peripheral structure 100 and the lower cell structure 205, respectively. In this case, during the planarization of the lower insulating layer 130, the peripheral sacrificial layer 25 and the cell sacrificial layer 120 may be used as the planarization stop layer.

After the planarization process, the lower insulating layer 130 may have no height difference or substantially no height difference. Thus, a locally planarized lower insulating pattern 135 may be formed between the lower cell structure 205 and the peripheral structure 100.

More specifically, the planarization of the lower insulating layer 130 may be performed using a chemical mechanical polishing (CMP) process. During the CMP process, the lower insulating layer 130 may be mechanically polished using a polishing pad configured to rotate on the substrate 10 (i.e., wafer) and simultaneously, chemically etched using a polishing solution with slurries, which may be supplied between the substrate 10 and the polishing pad.

In the meantime, a removal rate of the lower insulating layer 130 in the CMP process may be dependent upon various factors, such as a slurry type, a configuration of the polishing pad, a structure and type of a polishing head, a rotating speed of the polishing pad relative to the substrate 10, a pressure applied by the polishing pad to the substrate 10, and the material and shape of the lower insulating layer 130. Additionally, the slurry may be one selected to exhibit an excellent polishing property with respect to a target material, while the removal rate of the lower insulating layer 130 may depend on the slurry type and the kind of the target material.

According to some embodiments, the slurry supplied during the CMP process may have an etch selectivity (e.g., an etching rate of from 4:1 to 10:1) to the lower insulating layer 130 and the peripheral and cell sacrificial layers 25 and 120. For instance, the slurries for the CMP process may include at least one selected from silica, ceria, mangania, alumina, titania, zirconia, germania, or any combination thereof. When the lower insulating layer 130 is formed of silicon oxide and the peripheral and cell sacrificial layers 25 and 120 are formed of silicon nitride, silica and/or ceria slurries may be used for the CMP process.

Furthermore, an end-point detection (EPD) technique may be employed to control the CMP process. In the EPD technique, a polishing state of the lower insulating layer 130 may be monitored to determine a point in time at which the CMP process is finished. In some embodiments, the point in time at which the CMP process is finished may be determined in consideration of a change of operational characteristics (e.g., rotating speed) of the polishing pad and/or an optical change of monitoring light, which may occur when an underlying layer having a different removal rate from the lower insulating layer 130 is exposed during the CMP process. In other embodiments, the thickness of the lower insulating layer 130 may be monitored to determine a process time of the CMP process.

In the CMP process on the lower insulating layer 130, the cell sacrificial layer 120 may prevent an unintended polishing of the insulating layer 110 disposed there under, and the peripheral sacrificial layer 25 may prevent an unintended polishing of the peripheral insulating layer 23 disposed thereunder.

Referring to FIG. 5F, the peripheral sacrificial layer 25 and the cell sacrificial layer 120 may be removed after the planarization of the lower insulating layer 130. Thus, the peripheral structure 100, the lower cell structure 205 and the planarized lower insulating pattern 135 may have substantially the same vertical thickness or height on the substrate 10.

In detail, the peripheral sacrificial layer 25 and the cell sacrificial layer 120 may be removed by isotropic or anisotropic etching process, which is configured to have an etch selectivity to the insulating layer of the lower cell structure 205, the lower insulating pattern 135 and the peripheral insulating layer 23. For example, when the peripheral sacrificial layer 25 and the cell sacrificial layer 120 are formed of silicon nitride, they may be removed by an isotropic etching process using a phosphoric acid.

Referring to FIGS. 5G and 6B, an upper layered structure 300 may be formed on the peripheral structure 100, the lower cell structure 205 and the lower insulating pattern 135.

Like the lower layered structure 200, the upper layered structure 300 may include a plurality of insulating layers 110 and a plurality of sacrificial layers SC. Also, the upper layered structure 300 may be formed on the entire surface of the substrate 10.

As described with reference to FIG. 5B, the insulating layers 110 and the sacrificial layers SC may be alternately and repeatedly stacked using deposition processes. In the meantime, if the insulating layer 110 of the lower cell structure 205 is exposed at this step, the sacrificial layer SC of the upper layered structure 300 may be deposited earlier than the insulating layer 110 of the upper layered structure 300, or if the sacrificial layer SC of the lower cell structure 205 is exposed at this step, the insulating layer 110 of the upper layered structure 300 may be firstly deposited.

As described herein, the peripheral structure 100, the lower cell structure 205 and the lower insulating pattern 135 may have substantially the same thickness, and thus, the upper layered structure 300 can be formed without suffering from difficulties related to a height difference between the cell array region CAR and the peripheral circuit region PERI. Furthermore, a patterning process after forming the upper layered structure 300 can be performed without a process failure or defect caused by a height difference between the cell array region CAR and the peripheral circuit region PERI.

Referring to FIGS. 5H and 6C, penetrating structures 140 may be formed to penetrate the lower cell structure 205 and the upper layered structure 300 in the cell array region CAR. The penetrating structure 140 may be connected to the substrate 10.

In certain embodiments, the formation of the penetrating structures 140 may include patterning the lower cell structure 205 and the upper layered structure 300 to form openings exposing portions of the substrate 10 in the cell array region CAR, forming semiconductor patterns 141 in the openings, and forming contact pads 145 on the respective semiconductor patterns 141.

According to some embodiments, the formation of the openings may include forming a mask pattern (not shown), which defines positions of the openings, on the upper layered structure 300, and anisotropically etching the upper layered structure 300 and the lower cell structure 205 using the mask pattern as an etching mask.

The openings may be formed to expose sidewalls of the sacrificial layers SC and the insulating layers, and furthermore, they may penetrate the lower gate insulating layer 11 to expose a top surface of the substrate 10. According to some embodiments, the substrate 10 may be over-etched in the step of forming the openings, and thus, the top surface of the substrate 10 may be recessed to a predetermined depth as shown in the drawings. Each of the openings may have a shape with an aspect ratio (i.e., ratio of the depth of each of the openings to the width thereof) of at least five (5). In addition, as a result of the anisotropic etching process, the opening may have a width depending on a distance from the substrate 10. That is, the closer a distance from the substrate 10 is, the less the width of the opening is. According to some embodiments, each of the openings may be a cylindrical or hexahedral shaped hole, and the openings may be, two dimensionally or periodically, arranged on a top surface of the substrate 10 (i.e., xy-plane of FIG. 4). That is, the openings may be two dimensionally spaced apart from each other. According to other embodiments, from the plan view, the openings may be line-shaped trenches parallel to one another. According to still other embodiments, the openings may be arranged to in a zigzag pattern.

According to some embodiments, the formation of the semiconductor pattern 141 may include sequentially depositing a semiconductor layer and a gap-fill insulating layer in the openings and planarizing the semiconductor layer and the gap-fill insulating layer to expose a top surface of the upper layered structure 300.

In certain embodiments, the semiconductor layer may be deposited to a shorter thickness than half of the width of the opening. In addition, a horizontal thickness of the semiconductor pattern 141 may be smaller than a mean width of an inversion region, which may be formed in the semiconductor pattern 141 during an operation of the semiconductor memory device, or a mean size of silicon grains of the semiconductor pattern 141. In this case, the opening may be partially filled with the semiconductor pattern 141 and a central portion of the opening remains vacant. That is, the semiconductor pattern 141 may have a pipe shape, a hollow cylindrical shape, or a cup shape within the opening. Also, the vacant central region of the opening may be filled with a gap-fill insulating pattern 143 formed by patterning the gap-fill insulating layer. The gap-fill insulating pattern 143 may be formed of at least one insulating material having a good gap-filling property. For example, the gap-fill insulating pattern 143 may be formed of at least one of a high-density-plasma (HDP) oxide, a spin-on-glass (SOG) layer, or a CVD oxide.

According to other embodiments, the semiconductor layer may be deposited to a greater thickness than half of the width of the opening. Also, the semiconductor layer may be planarized by etching until the top surface of the upper layered structure 300 is exposed. As a result, the semiconductor pattern 141 may have a solid cylindrical shape and fill the opening.

In the meantime, when the openings have a line shape, insulating patterns may be interposed between the semiconductor patterns 141 in each of the openings. More specifically, the semiconductor layer and the gap-fill insulating layer formed in the openings may be patterned across the openings. As a result, the semiconductor pattern 141 may have a substantially rectangular cross-section from the plan view.

The semiconductor pattern 141 may be formed of, for example, silicon (Si), germanium (Ge), or a combination thereof. The semiconductor pattern 141 may be formed of a doped semiconductor or an undoped (i.e., intrinsic) semiconductor. The semiconductor pattern 141 may be formed to have one of a single-crystalline structure, an amorphous structure, or a polycrystalline structure. The semiconductor pattern 141 may be formed in the respective openings 131 by a chemical vapor deposition (CVD) process or an atomic layer deposition (ALD) process. In the case, due to a difference in a crystalline structure, a discontinuous boundary may be formed between the semiconductor pattern 141 and the substrate 10. According to some embodiments, the semiconductor pattern 141 may partially include at least a single-crystalline structure obtained from a phase transition of the deposited amorphous or polycrystalline silicon layer. The phase transition may be realized by a thermal treatment such as a laser annealing process. According to other embodiments, the semiconductor pattern 141 may be formed in the respective openings by an epitaxial process using the substrate 100 exposed by the openings as a seed layer.

The contact pads 145 may be formed on top surfaces of the gap-fill insulating pattern 143 and the semiconductor pattern 141. The contact pads 145 may be formed of at least one of doped polysilicon, a metallic material, or a conductive material. In certain embodiments, the contact pads 145 may have a different conductivity type from the semiconductor pattern 141, and thus the contact pads 145 and the semiconductor pattern 141 may constitute a rectifying element (e.g., diode).

According to some embodiments, the formation of the contact pads 145 may include partially recessing top surfaces of the gap-fill insulating patterns 143 and filling a gap region formed by recessing the gap-fill insulating patterns 143 with a conductive pattern (e.g., polysilicon pattern or metallic pattern). According to other embodiments, the formation of the contact pads 145 may include depositing a conductive layer on the upper layered structure 300 having the semiconductor patterns 141 and patterning the conductive layer to form conductive patterns on the respective semiconductor patterns 141. The conductive layer may be formed of a metallic material (e.g., tungsten). For example, the formation of the conductive layer may include sequentially forming a barrier metal layer (e.g., a metal nitride layer) and a metal layer (e.g., a tungsten layer). According to still other embodiments, the formation of the contact pads 145 may include forming an upper insulating layer (not shown) on the upper layered structure 300, patterning the upper insulating layer to form holes exposing the semiconductor patterns 141, and forming polysilicon patterns in the holes. According to yet other embodiments, the contact pads 145 may be formed by implanting impurity ions of a different conductivity type from the semiconductor pattern 141 into upper portions of the semiconductor patterns 141.

In the meantime, as will be described with reference to FIG. 5I, the formation of the penetrating structures 140 in the cell array region CAR may be achieved by forming the stepwise upper cell structure 305, as in the formation of the lower cell structure 205.

Referring to FIG. 5I, the upper layered structure 300 may be patterned to form the upper cell structure 305 on the lower cell structure 205.

The upper cell structure 305 may be formed by patterning the upper layered structure 300 several times, similar to the formation of the lower cell structure 205 described with reference to FIG. 5C. According to some embodiments, the patterning of the upper layered structure 300 may include reducing an area occupied by the mask pattern using a lateral etching process and etching exposed edge portions of the upper layered structure 300 using a vertical etching process, which may be alternately and repeatedly performed. As a result, the stepwise upper cell structure 305 may be formed on the lower cell structure 205. That is, the lower insulating pattern 135 and the peripheral structure 100 are exposed by the upper cell structure 305.

In detail, the upper cell structure 305 may have a stepwise contact portion, which extends from the cell array region CAR to the contact region CTR. As a result, the contact portions of the upper and lower cell structures 305 and 205 may have collectively a stepwise shape in the contact region CTR. For example, for two vertically adjacent sacrificial layers SC among the lower and/or upper cell structures 205 and 305, a horizontal distance between their sidewalls may be substantially the same. Furthermore, according to some embodiments, in the lower and upper cell structures 205 and 305, the number of the sacrificial layers SC may be the same as the number of the conductive patterns 180 to be stacked in the cell array region CAR. Although the upper cell structure 305 may have different heights in the cell array region CAR and the peripheral circuit region PERI, the height difference may be less than a distance from the substrate 10 to a top surface of the upper cell structure 305.

According to some embodiments, thicknesses of the sacrificial layers SC of the lower and upper cell structures 205 and 305 may be substantially the same. According to other embodiments, uppermost and lowermost sacrificial layers SC may be thicker than other sacrificial layers SC. Alternatively, one of the insulating layers 110 may be thicker than another of the insulating layers. In considerations for various factors, such as transistors' electrical properties and patterning difficulties, the lower and upper cell structures 205 and 305 may be variously modified in terms of the number, thicknesses and material layers thereof.

Next, referring to FIG. 5J, an upper insulating layer 160 may be formed on the peripheral circuit region PERI and the contact region CTR of the substrate 10.

The upper insulating layer 160 may be formed of a material having an etch selectivity to the sacrificial layers SC during the removal of the sacrificial layers SC from the lower and upper cell structures. Alternatively, the upper insulating layer 160 may be formed of a material having an etch selectivity to both the insulating layers and the sacrificial layers SC of the lower layered structure.

The upper insulating layer 160 may be formed using a PVD method, a CVD method, a SACVD method, a LPCVD method, a PECVD method or a HDP CVD method. Since the upper insulating layer 160 is formed using the deposition method, a resultant structure disposed on the substrate 10 may be conformally covered with the upper insulating layer 160 in at least the cell array region CAR and the peripheral circuit region PERI. Also, the upper insulating layer 160 may be deposited to a greater thickness than a height difference between the top surfaces of the upper cell structure 305 and the peripheral structure 100. The deposited upper insulating layer 160 may have a different height in the cell array region CAR than in the peripheral circuit region PERI.

Subsequently, a planarization process may be performed on the upper insulating layer 160 to expose the penetrating structure 140 in the cell array region CAR. Here, the planarized upper insulating layer 160 may cover the upper cell structure 305 in the contact region CTR and the peripheral structure 100 in the peripheral circuit region PERI.

The upper insulating layer 160 may be, for example, formed of at least one of HDP oxide, TEOS, PE-TEOS, O3-TEOS, USG, PSG, BSG, BPSG, FSG, SOG, TOSZ or any combination thereof. Alternatively, the upper insulating layer 160 may include at least one of silicon nitride, silicon oxynitride or a low-k dielectric.

According to some embodiments, before forming the upper insulating layer 160, a buffer insulating layer 150 may be conformally formed on the upper cell structure 305, the planarized lower insulating pattern 135, and the peripheral structure 100.

That is, the buffer insulating layer 150 may be formed to cover top surfaces of the lower insulating pattern 135 and the peripheral structure 100 and exposed surfaces of the upper cell structure 305. For example, the buffer insulating layer 150 may cover top surfaces of the contact pads 145 in the cell array region CAR or the stepwise portion of the upper cell structure 305 in the contact region CTR.

In certain embodiments, the buffer insulating layer 150 may be formed of a material having an etch selectivity to the upper cell structure 305. In detail, the buffer insulating layer 150 may be formed of a material having an etch selectivity to at least one of the sacrificial layers SC and the insulating layers of the upper cell structure 305. For example, the buffer insulating layer 150 may include at least one of silicon nitride (SiN), silicon oxynitride (SiON), silicon carbide (SiC), or silicon oxycarbide (SiOC).

In certain embodiments, the buffer insulating layer 150 may include a first buffer layer 150a having an etch selectivity to the sacrificial layers SC and a second buffer layer 150b having an etch selectivity to the insulating layers. The first buffer layer 150a may conformally cover the exposed surfaces of the patterned upper cell structure 305, the lower insulating pattern 135, and the peripheral structure 100. That is, the first buffer layer 150a may cover sidewalls of the sacrificial layers SC in the contact region CTR, and the second buffer layer 150b may be conformally formed on the first buffer layer 150a. In certain embodiments, the first buffer layer 150a may be formed of silicon oxide, and the second buffer layer 150b may be formed of silicon nitride. Meanwhile, according to other embodiments, the buffer insulating layer 150 may be a single layer, which is formed of a material having an etch selectivity to both the sacrificial layers SC and the insulating layers.

Referring to FIG. 5K, FIG. 5L, and FIGS. 6D through 6F, the sacrificial layers SC in the lower and upper cell structures 305 may be replaced with conductive patterns 180 by performing a replacement process.

In detail, the replacement process may include forming trenches 171 exposing the substrate 10 between the adjacent semiconductor patterns 141, removing the sacrificial layers SC through the trenches 171 to form recess regions 173 between the insulating layers, and forming conductive patterns 180 in the recess regions 173. Furthermore, in certain embodiments, before forming the conductive patterns 180, a data storage layer DS may be conformally formed to cover the recess regions 173.

Referring to FIG. 6D, the formation of the trenches 171 may include forming a mask pattern (not shown) defining a two-dimensional arrangement of the trenches 171 on the upper cell structure 305 and anisotropically etching the upper and lower cell structures 305 and 205 using the mask pattern as an etch mask.

In certain embodiments, the trenches 171 may be spaced apart from the semiconductor patterns 141 to expose sidewalls of the sacrificial layers SC and the insulating layers. In horizontal view, the trenches 171 may have a line or rectangular shape, and in vertical depth, the trenches 171 may be formed to expose at least a top surface of the lowest one of the sacrificial layers SC. According to some embodiments, during the formation of the trenches 171, the top surface of the substrate 10 may be recessed to a predetermined depth by over-etching. In addition, as a result of the anisotropic etching process, the trench 171 may have a different width according to a distance from the substrate 10. For example, the closer the distance from the substrate 10 is, the less the width of the trench 171 is.

Due to the trenches 171, the lower and upper cell structures 205 and 305 may be patterned to have line-shaped portions running along the major axis of the trench 171, as shown in FIG. 4. Also, a plurality of semiconductor patterns 141, which are arranged along the major axis of the trench 171, may penetrate one of the line-shaped portions of the lower and upper cell structures 205 and 305. The lower and upper cell structures 205 and 305 may have inner sidewalls adjacent to the semiconductor patterns 141 and outer sidewalls exposed by the trenches 171. In the meantime, in some embodiments, the trench 171 may have the line shape not to cross the contact region CTR. That is, each of the lower and upper cell structures 205 and 305 may have an edge-portion, which remains in the contact region CTR and connects the line-shaped portions thereof with each other. For example, the lower and upper cell structures 205 and 305 may be a comb-shaped or finger-shaped structure.

According to some embodiments, after the formation of the trenches 171, impurity regions 175 may be locally formed in the substrate 10 exposed by the trenches 171, and they may serve as the common source line described with reference to FIG. 3. That is, the lower and upper cell structures 205 and 305 having the trenches 171 may be used as an ion mask during an ion implantation process for forming the impurity region 175. Accordingly, the impurity region 175 may have a line shape extending in one direction like a horizontal shape of the trench. Moreover, the impurity region 175 may horizontally overlap a portion of the lower region of the lower and upper cell structures 205 and 305 due to the diffusion of impurities. Additionally, the impurity region 175 may have a different conductivity type from the substrate 10.

Referring to FIGS. 5K and 6E, the formation of the recess regions 173 may include isotropically etching the sacrificial layers SC having sidewalls exposed by the trenches 171, using an etch recipe having an etch selectivity to the insulating layers. Here, the sacrificial layers SC may be removed using the isotropic etching process, so that a portion of a sidewall of the semiconductor pattern 141 may be exposed by the recess region. For example, if the sacrificial layers SC are formed of silicon nitride and the insulating layers 110 are formed of silicon oxide, the isotropic etching process may be performed using an etchant containing a phosphoric acid. The recess region 173 may be a vacant region that horizontally extends from the trench 171 and exposes a portion of the sidewall of the semiconductor pattern 132. Also, the lowermost recess region 173 may have a bottom surface defined by the lower gate insulating layer 11. A vertical thickness of the recess region 173 may be determined by a deposited thickness of the corresponding sacrificial layer SC, as described with reference to FIGS. 5A and 5B.

Referring to FIGS. 5L and 6F, conductive patterns 180 may be formed in the recess regions 173.

In detail, the recess regions 173 and the trenches 171 may be filled with a conductive layer, and then the conductive layer may be removed from the trenches 171. The conductive patterns 180 may be provided as residues of the conductive layer, which are vertically separated from each other.

The conductive layer may be formed using a deposition technique (e.g., a CVD or ALD technique) capable of providing an excellent step coverage property. Accordingly, the conductive layer may be conformally formed in the trench 171 to fill the recess regions 173. Here, the conductive layer may be deposited to a greater thickness than half of that of the recess region 173. Moreover, if a horizontal width of the trench 171 is greater than the thickness of the recess region 173, the conductive layer may partially fill the trench 171, and an upwardly opened empty region may be formed at the center of the trench 171. The conductive layer may include at least one of doped polysilicon, tungsten, metal nitrides, or metal silicides. According to some embodiments, the formation of the conductive layer may include sequentially forming a barrier metal layer (e.g., a metal nitride layer) and a metal layer (e.g., a tungsten layer). Moreover, the inventive concepts are not limited to flash memory devices and thus a material and structure of the conductive layer may be variously changed.

The removal of the conductive layer from the trench 171 may include anisotropically etching the conductive layer using the uppermost insulation layer of the upper cell structure 305 or an additional hard mask pattern (not shown) formed on the upper cell structure 305 as an etching mask. The top surface of the substrate 10 or the data storage layer DS disposed thereon may be re-exposed using this anisotropic etching process. Moreover, a top surface of the substrate 100 may be recessed as shown in the drawings.

According to some embodiments, the conductive patterns 180 may constitute gate structures GP. In certain embodiments, as shown in FIG. 4, each of the gate structures GP may have a line shape elongated along a direction parallel to the trench 171 and may be penetrated by a plurality of the semiconductor patterns 141 arranged along the direction parallel to the trench 171. The conductive patterns 180 may have outer sidewalls adjacent to the trench 171 and inner sidewalls adjacent to the semiconductor pattern 141. The inner sidewalls of the conductive patterns 180 may surround the semiconductor patterns 141 or run across at least one of the sidewalls of the semiconductor pattern 141. Meanwhile, the conductive patterns 180, which are disposed in one block of memory cell array, may be connected to each other in the contact region CTR to form a comb or finger-shaped structure.

According to this embodiment, the stacked conductive patterns 180 may serve as the string selection line SSL, the ground selection line GSL, and the word lines WL described with reference to FIG. 2. For example, the uppermost and lowermost layers of the conductive patterns 180 serve as the string selection line SSL and the ground selection line GSL, respectively, and the conductive patterns 180 therebetween may serve the word lines WL. Alternatively, as described with reference to FIG. 3, two uppermost layers of the conductive patterns 180 may serve as the string selection line SSL of FIG. 2, and two lowermost layers of the conductive patterns 180 may serve as the ground selection line GSL of FIG. 2. The conductive patterns 180 serving as the string or ground selection lines SSL or GSL of FIG. 2 may be horizontally separated from each other. In this embodiment, the string or ground selection lines may be electrically separated from each other even at the same level.

According to some embodiments, after forming the gate structures GP, a separation insulating layer 185 may be formed between the adjacent gate structures GP. The separation insulating layer 185 may be formed of at least one of silicon oxide, silicon nitride, or silicon oxynitride.

Meanwhile, in certain embodiments, the data storage layer DS may be formed before forming the conductive patterns 180 in the recess regions 173.

According to some embodiments, information stored in the data storage layer DS may be changed using FN tunneling caused by a voltage difference between the semiconductor pattern 141 and the gate electrode (e.g., WL of FIG. 4). For example, the data storage layer DS may be one of a charge trap insulating layer, a floating gate electrode or an insulating layer having conductive nano dots.

Meanwhile, the data storage layer DS may be formed of materials based on different data-writing principles. For example, the data storage layer DS may include one of materials having a variable resistance property or a phase changeable property.

According to some embodiments, as shown in FIGS. 5K and 6F, the data storage layer DS may be conformally formed on exposed surfaces of the lower and upper cell structures 205 and 305 having the recess regions 173.

The data storage layer DS may be formed using a deposition technique (e.g., a CVD or ALD technique) capable of providing an favorable step coverage property. The data storage layer DS may be formed to a smaller thickness than half of the thickness of the recess regions 173. That is, the data storage layer DS may be formed to partially cover the sidewalls of the semiconductor pattern exposed by the recess regions 173, and it may be extended on bottom and top surfaces of the insulating patterns defining the recess regions 173. In addition, the data storage layer DS may be deposited to cover the top surface of the substrate 10 under the trench 171 and the top surface of the upper cell structure 305. The data storage layer DS may cover a top surface of the lower gate insulating layer 11 exposed by the lowermost recess region 173.

According to other embodiments, as shown in FIG. 7A, the data storage layer DS may be locally interposed between the vertically adjacent insulating layers 110. For example, the data storage layer DS may be patterned to expose sidewalls of the insulating layers 110. In this case, the data storage layer DS may include portions partially disposed within the respective recess regions 173, so that a charge spreading phenomenon can be prevented from occurring between the portions of the data storage layer DS.

In addition, as shown in FIGS. 7B and 7D, the data storage layer DS between the semiconductor pattern 141 and the conductive pattern 180 may include a tunnel insulating layer DS1, a charge trap layer DS2, and a blocking insulating layer DS3 stacked sequentially.

The tunnel insulating layer DS1 may be formed to be in directly contact with the semiconductor pattern 141. Also, the tunnel insulating layer DS1 may have a lower dielectric constant than the blocking insulating layer DS3. For example, the tunnel insulating layer DS1 may include at least one of oxide, nitride, or oxynitride.

The charge trap layer DS2 may be an insulating layer (e.g., a silicon nitride layer) having rich charge trap sites or an insulating layer having conductive grains.

The blocking insulating layer DS3 may include at least one of silicon oxide, silicon nitride, silicon oxynitride, and high-k dielectrics, and it may be a multilayered structure including a plurality of layers. Here, the high-k dielectrics refer to insulating materials having a higher dielectric constant than silicon oxide (e.g., tantalum oxide, titanium oxide, hafnium oxide, zirconium oxide, aluminum oxide, yttrium oxide, niobium oxide, cesium oxide, indium oxide, an iridium oxide, barium-strontium-titanate (BST) materials, and lead-zirconium-titanate (PZT) materials).

In certain embodiments, the tunnel insulating layer DS1 may include silicon oxide, the charge trap layer DS2 may include silicon nitride, and the blocking insulating layer DS3 may include aluminum oxide.

Although not depicted, according to other embodiments, the blocking insulating layer DS3 may include a first blocking insulating layer and a second blocking insulating layer. Here, the first and second blocking insulating layers may formed of different materials, and one of the first and second blocking insulating layers may include a material having a bandgap which is narrower than the tunnel insulating layer and wider than that of the charge trap layer. For instance, the first blocking insulating layer may be formed of one of high-k dielectrics (e.g., aluminum oxide and hafnium oxide), and the second blocking insulating layer may be formed of a material having a smaller dielectric constant than the first blocking insulating layer. According to other embodiments, the second blocking insulating layer may be formed of one of high-k dielectrics, and the first blocking insulating layer may be formed of a material having a smaller dielectric constant than the second blocking insulating layer.

According to modified embodiments, the data storage layer DS may also include the tunnel insulating layer DS1, the charge trap layer DS2, and the blocking insulating layer DS3 stacked sequentially, but as shown in FIG. 7B, the tunnel insulating layer DS1 and the charge trap layer DS2 may run across the conductive patterns 180 and cover the outer sidewall of the semiconductor pattern 141. In these embodiments, the tunnel insulating layer DS1 and the charge trap layer DS2 may be formed on the inner wall of the opening before the formation of the semiconductor pattern 141 described with reference to FIGS. 7A and 7B, and the blocking insulating layer DS3 may be conformally formed on inner surfaces of the recess region 173 after forming the recess regions 173. Accordingly, the blocking insulating layer DS3 may be in directly contact with top and bottom surfaces of the insulating layers 110. According to other modified embodiments, as shown in FIG. 7C, the tunnel insulating layer DS1 may be formed to cover the inner wall of the opening before forming the semiconductor pattern 141, and the charge trap layer DS2 and the blocking insulating layer DS3 may be conformally and sequentially formed on the inner surface of the recess region 173.

Referring to FIGS. 5L and 6G, an interconnection structure including contact plugs WPLG and PPLG and wirings GWL may be formed to connect the conductive patterns 180 disposed in the cell array region CAR with the peripheral circuits disposed in the peripheral circuit region PERI.

For example, bit line contact plugs BPLG may be formed in the cell array region CAR, the word line contact plugs WPLG may be formed in the contact region CTR, and the peripheral contact plugs PPLG may be formed in the peripheral circuit region PERI.

The formation of the contact plugs BPLG, WPLG, and PPLG may include forming contact holes though the insulating layers 23, 135 and 160 in the contact region CTR and the peripheral circuit region PERI and filling the contact holes with a conductive material. In certain embodiments, the contact plugs BPLG, WPLG, and PPLG may be formed of a metallic material (e.g., tungsten). In this case, the formation of the contact plugs BPLG, WPLG, and PPLG may include sequentially forming a barrier metal layer (e.g., a metal nitride layer) and a metal layer (e.g., a tungsten layer).

The bit line plugs BPLG may be connected to the contact pads 145 of the penetrating structure 140, the word line contact plugs WPLG may be respectively connected to the conductive patterns 180, and the peripheral contact plugs PPLG may be respectively connected to the peripheral circuits. The conductive patterns 180 disposed at different levels may be connected to different ones of the word line contact plugs WPLG.

In addition, bit lines BL may be formed on the bit line plugs BPLG, and global word lines GWL may be formed on the upper insulating layer 160. The bit lines BL may cross over the conductive patterns 180 and the word line contact plugs WPLG may be coupled to the peripheral contact plugs PPLG through the global word lines GWL. For example, the conductive patterns 180 disposed in the cell array region CAR may be electrically connected to the peripheral circuits by the word line contact plugs WPLG, the global word lines GWL, and the peripheral contact plugs PPLG. In some embodiments, the peripheral circuits may be configured to apply the same voltage to a plurality of the conductive patterns 180 located at the same level.

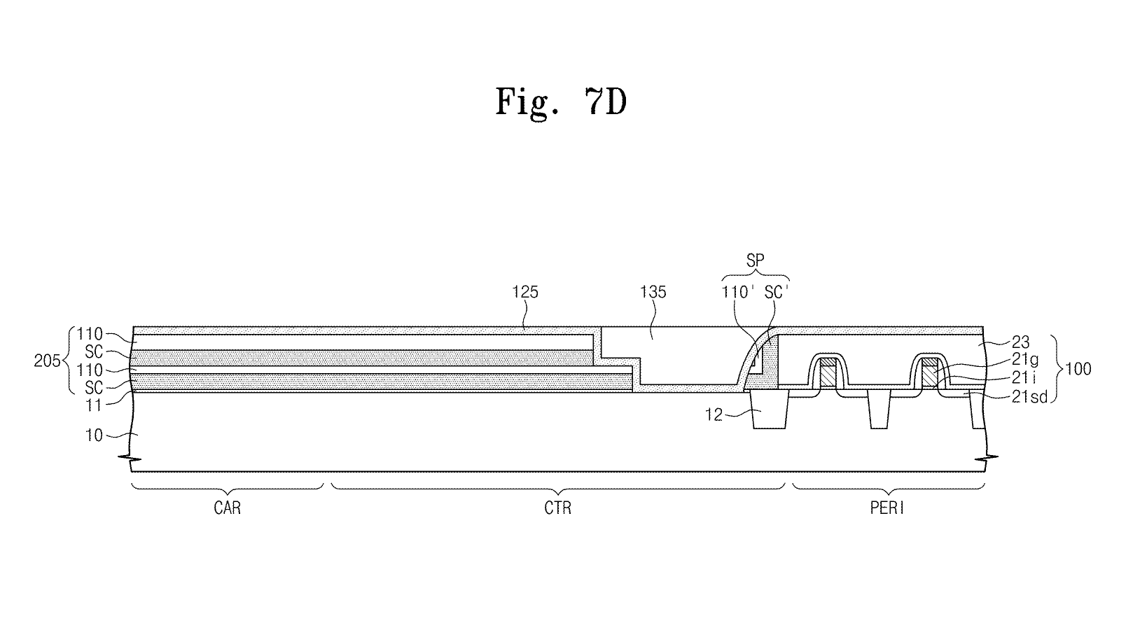

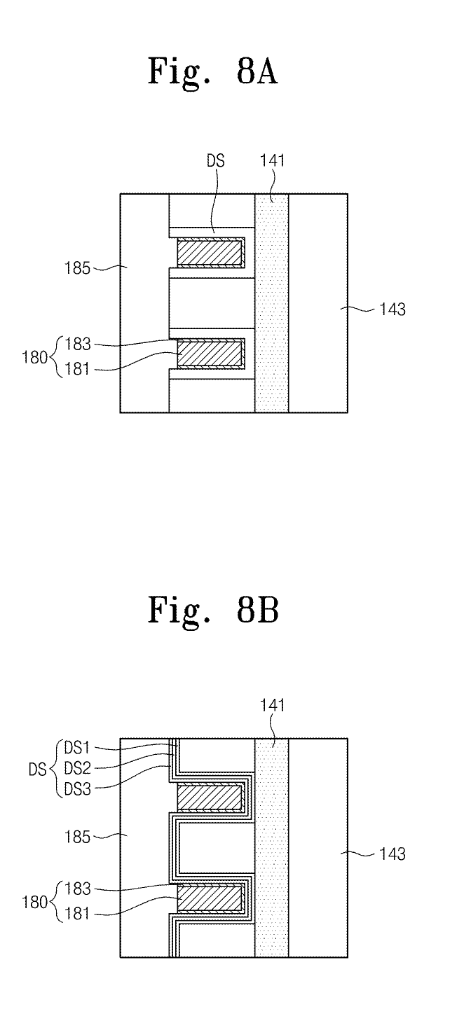

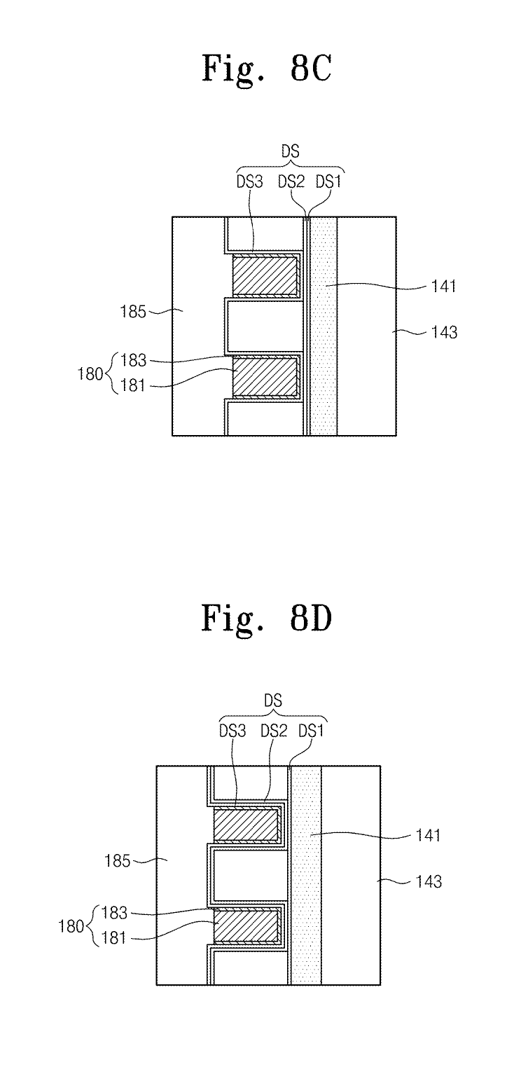

A method of fabricating a three-dimensional semiconductor device according to second embodiments of the inventive concepts will be described with reference to FIGS. 8A through 8D. In detail, FIGS. 8A through 8D are cross-sectional views illustrating a portion of a cell array region of the three-dimensional semiconductor memory device, taken along an xz-plane of FIG. 4, and a portion of the peripheral region PERI according to the second embodiment.

In these embodiments, the same elements as in the embodiments described with reference to FIGS. 5A through 5L will be denoted by the same reference numbers as in the embodiments described with reference to FIGS. 5A through 5L, and a description thereof may be omitted here for brevity's sake.

Referring to FIG. 8A, a peripheral structure 100 and a lower cell structure 205 may be respectively formed on a peripheral circuit region PERI and a cell array region CAR, as described with reference to FIGS. 5A through 5C.

The peripheral structure 100 may include peripheral circuits and a peripheral insulating layer 23 covering the peripheral circuits, and the lower cell structure 205 may include a plurality of insulating layers and a plurality of sacrificial layers SC. Here, the numbers of the insulating layers and the sacrificial layers SC may be different than in FIG. 8A.

As mentioned above, a thickness difference between the lower cell structure 205 and the peripheral structure 100 may be less than the thickness of the lower cell structure 205 or the peripheral structure 100. For example, the lower cell structure 205 may have substantially the same thickness or height as the peripheral structure 100. Also, the lower cell structure 205 and the peripheral structure 100 may be apart from each other not to cover a top surface of the substrate 10 therebetween. In addition, the spacer SP may be disposed on one of sidewalls of the peripheral structure 100 adjacent to the cell array region CAR, and it may include at least one layer made of the same material as the sacrificial layer SC and the insulating layer of the lower cell structure 205.

Referring to FIG. 8B, a planarization stop layer 125 may be conformally formed on the substrate 10 having the peripheral structure 100 and the lower cell structure 205.

According to some embodiments, the planarization stop layer 125 may be formed of at least one of materials having an etch selectivity to the lower cell structure 205 and the peripheral structure 100. For example, the planarization stop layer 125 may have an etch selectivity to uppermost layers of the lower cell structure 205 and the peripheral structure 100. In certain embodiments, the planarization stop layer 125 may include at least one of silicon nitride (SiN), silicon oxynitride (SiON), silicon carbide (SiC), or silicon oxycarbide (SiOC). Furthermore, the planarization stop layer 125 may have a double layered structure (e.g., the buffer insulating layer 150 described with reference to FIG. 5J) or a single layered structure as shown in FIG. 8B.

Referring to FIG. 8C, a lower insulating layer 130 may be formed on the planarization stop layer 125.

The lower insulating layer 130 may be deposited on the substrate 10 in the cell array region CAR and the peripheral circuit region PERI to conformally cover exposed surfaces of the planarization stop layer 125. The lower insulating layer 130 may be formed to a greater thickness than the peripheral structure 100 or the lower cell structure 205 to fill a gap region between the peripheral structure 100 and the lower cell structure 205. The lower insulating layer 130 may be formed of a material having an etch selectivity to the planarization stop layer 125.

Referring to FIG. 8D, the lower insulating layer 130 is planarized by a planarization process using the planarization stop layer 125 as an etch stop layer 130.

A lower insulating pattern 135 having a partially flat top surface may be formed by the planarization process between the lower cell structure 205 and the peripheral structure 100. That is, a local height difference of the lower insulating layer 130, which was caused by the deposition process, can be removed by the planarization process. The planarization process of the lower insulating layer 130 may be performed using a chemical-mechanical polishing process, as described above. Here, the planarization stop layer 125 can prevent an unintentionally polishing of the lower cell structure 205 and the peripheral structure 100.

After planarizing the lower insulating layer 130, the planarization stop layer 125 may be removed from the top surfaces of the lower cell structure 205 and the peripheral structure 100. Accordingly, the top surfaces of the lower cell structure 205 and the peripheral structure 100 may be exposed, and the planarization stop layer 125 may partially remain between the lower cell structure 205 and the peripheral structure 100. That is, the peripheral structure 100, the lower cell structure 205, and the planarized lower insulating pattern 135 may have substantially the same vertical thickness or height on the substrate 10.

After forming the lower insulating pattern 135, an upper cell structure, a data storage layer and conductive patterns are formed on the resultant structure, as described with reference to FIGS. 5G through 5L.

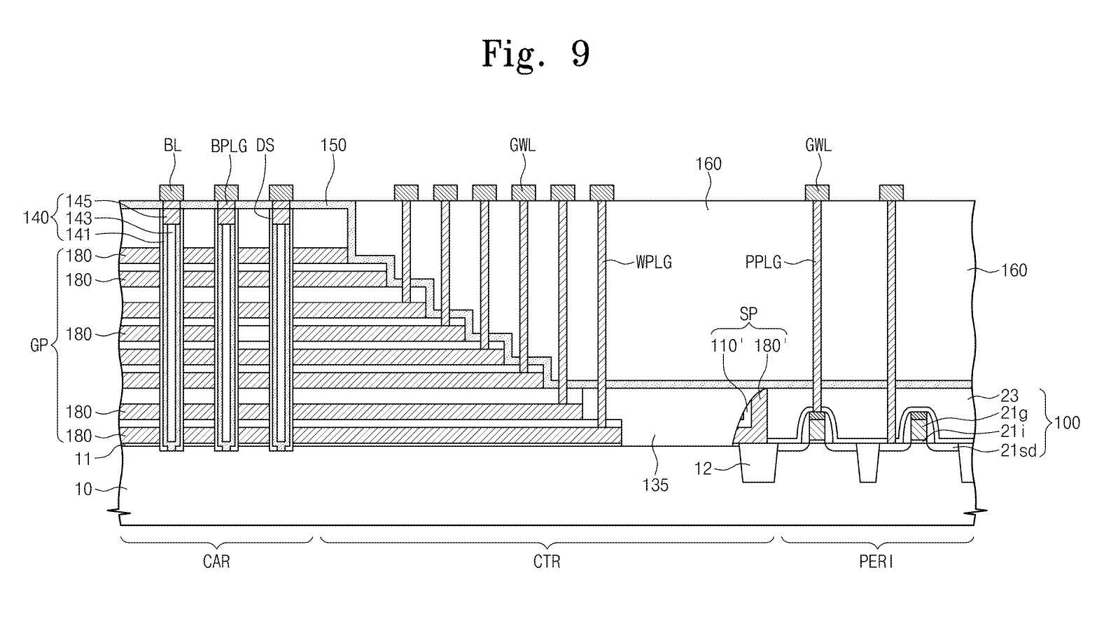

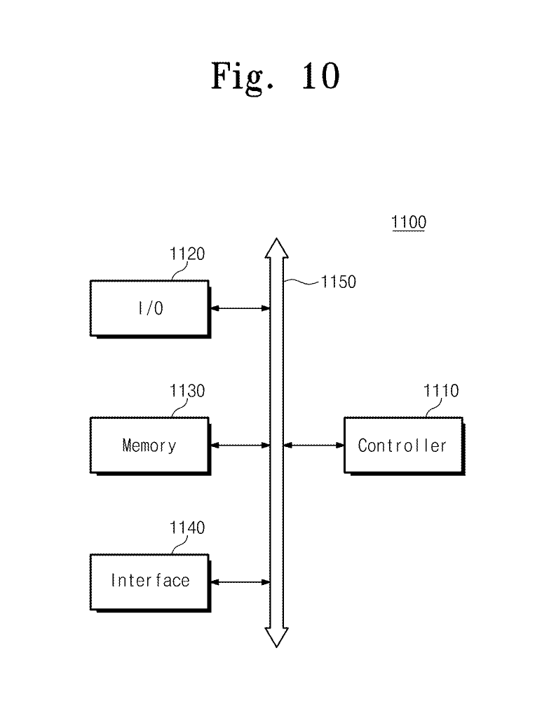

FIG. 9 is a cross-sectional view illustrating a three-dimensional semiconductor memory device according to third embodiments of the inventive concepts. In the third embodiment, substantially the same elements will be denoted by the same reference number as in the first embodiment, and a detailed description thereof may be omitted.

According to the third embodiment, as described with reference to FIGS. 5A through 5C, the peripheral structure 100 is formed on the peripheral circuit region PERI, and the lower cell structure 205 having substantially the same thickness as the peripheral structure 100 may be formed on the whole top surface of the resultant structure. Next, as described with reference to FIGS. 5D through 5F, the lower insulating pattern 135 may be formed to substantially the same thickness as the peripheral structure 100 and the lower cell structure 205 between the peripheral structure 100 and the lower cell structure 205. And, as described with reference to FIGS. 5G through 5I, the upper cell structure 305 may be formed on the lower cell structure 205. Here, each of the lower and upper cell structures 205 and 305 may include gate conductive layers and insulating layers stacked alternately and repeatedly.

The gate conductive layers may be formed of polysilicon or amorphous silicon doped with a P-type dopant (e.g., boron) or an N-type dopant (e.g., phosphorous). In addition, a lower gate insulating layer 11 may be formed to a very small thickness between the lowermost gate conductive layer and the substrate 10, and the lower gate insulating layer 11 may be formed of oxide (e.g., thermal oxide).

Meanwhile, in the third embodiment, the lower cell structure 205 may be formed by patterning the lower layered structure 200 including the sacrificial layers SC and the insulating layers stacked alternately and repeatedly. Therefore, a spacer SP may be provided as a residue of the lower layered structure 200 on a sidewall of the peripheral structure 100. That is, the spacer SP may include a conductive pattern 180′ and an insulating pattern 110′ obtained by patterning the sacrificial layer SC and the insulating layer. Here, the conductive pattern 180′ of the spacer SP may have substantially the same material and thickness as the lowermost gate conductive layer of the lower cell structure 205, and the insulating pattern 110′ of the spacer SP may have substantially the same material and thickness as the lowermost insulating layer 110 of the lower cell structure 205.

In these embodiments, the gate conductive layers included in the lower and upper cell structures 205 and 305 may be used as word lines WL01 to WL3 and selection lines GSL and SSL described with reference to FIG. 2. Thus, the channel length of the memory cell transistor (e.g., MCT in FIG. 2) may be determined by the thicknesses of the gate conductive layers included in the lower and upper cell structures 205 and 305. In certain embodiments, since the gate conductive layers are formed using deposition processes, the channel length can be controlled more precisely than when patterning methods are used.

A distance between the gate conductive layers (i.e., a distance between the insulating layers) may be less than the maximum vertical length of an inversion region, which may be induced in the semiconductor pattern 141 to be formed subsequently. According to some embodiments, the gate conductive layers may be formed to have substantially the same thickness. Otherwise, the uppermost and lowermost ones of the gate conductive layers may be thicker than the others. According to other embodiments, one of the insulating layers may be thicker than the others. In consideration of some factors, such as transistors' electrical properties and patterning difficulties, the lower and upper cell structures 205 and 305 may be variously modified in terms of the numbers, thicknesses and material layers thereof.

Meanwhile, according to these embodiments, an impurity region serving as the common source line CSL of FIG. 2 may be formed in the substrate 10 before forming the lower layered structure 200.

According to these embodiments, the data storage layer DS may be formed before forming the penetrating structure 140 described with reference to FIG. 5H.

In detail, the lower and upper cell structures 305 may be patterned to form openings exposing the substrate 10, and the data storage layer DS may be conformally deposited in the openings. Since the data storage layer DS is formed using a deposition technique, the data storage layer DS can be conformally deposited on the top surface of the substrate 10 exposed by the opening.

Meanwhile, the penetrating structure 140 formed in the opening may be electrically connected to the substrate 10. To enable this electrical connection, the data storage layer DS may be partially removed from the top surface of the substrate 10 in the openings, before forming the penetrating structure 140.

In third embodiments, since the gate conductive layers are included in the lower and upper cell structures 305, the replacement process of the first embodiments described with reference to FIG. 5K, FIG. 5L, and FIGS. 6D through 6F may be omitted.

FIG. 10 is a block diagram illustrating an example of a memory system including a semiconductor memory device according to some embodiments of the inventive subject matter.

Referring to FIG. 10, a memory system 1100 can be applied to a PDA (personal digital assistant), a portable computer, a web tablet, a wireless phone, a mobile phone, a digital music player, a memory card and/or all the devices that can transmit and/or receive data in a wireless communication environment.

The memory system 1100 includes a controller 1110, an input/output device 1120 such as a keypad and a display device, a memory 1130, an interface 1140 and a bus 1150. The memory 1130 and the interface 1140 communicate with each other through the bus 1150.

The controller 1110 includes at least one microprocessor, at least one digital signal processor, at least one micro controller or other process devices similar to the microprocessor, the digital signal processor and the micro controller. The memory 1130 may be used to store an instruction executed by the controller 1110. The input/output device 1120 can receive data or a signal from the outside of the system 1100 or transmit data or a signal to the outside of the system 1100. For example, the input/output device 1120 may include a keyboard, a keypad and/or a displayer.

The memory 1130 includes the nonvolatile memory device according to embodiments of the inventive subject matter. The memory 1130 may further include a different kind of memory, a volatile memory device capable of random access and various kinds of memories.

The interface 1140 transmits data to a communication network or receives data from a communication network.

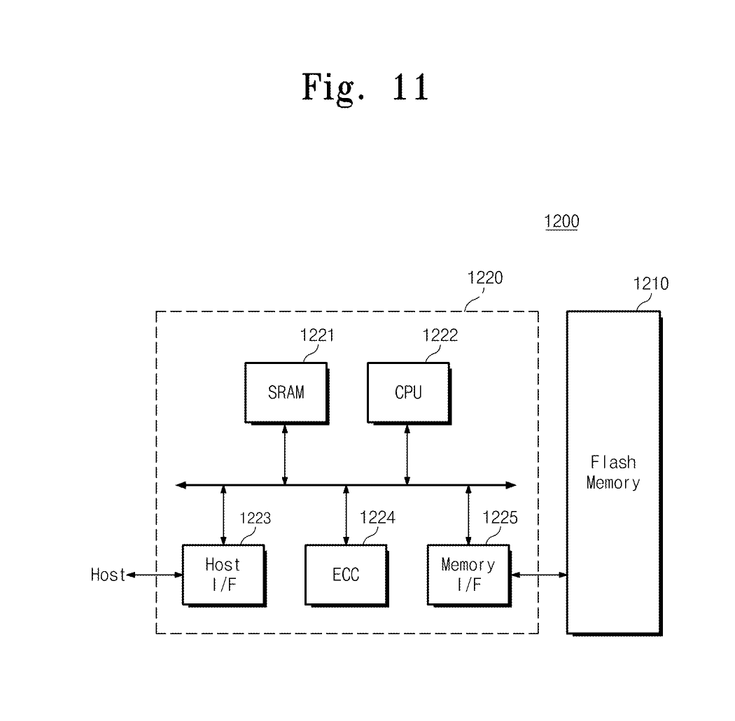

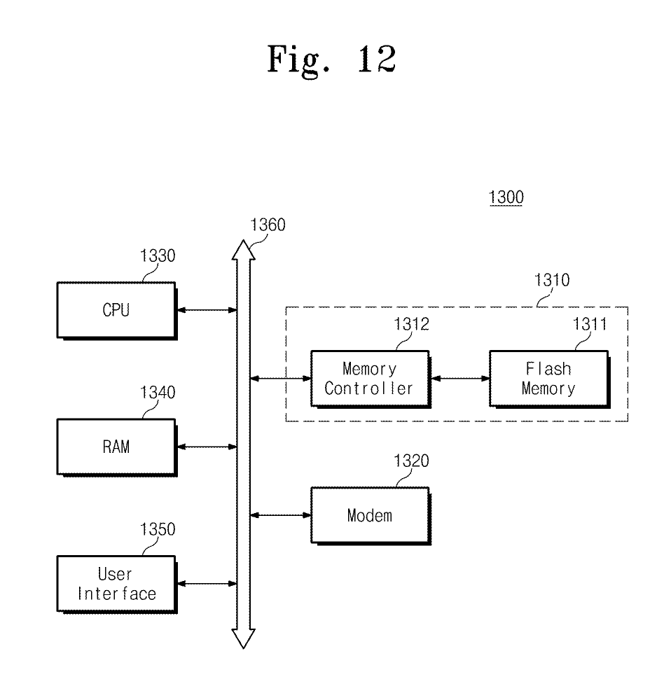

FIG. 11 is a block diagram illustrating an example of a memory card including a semiconductor memory device according to some embodiments of the inventive subject matter.

Referring to FIG. 11, the memory card 1200 for supporting a storage capability of a large capacity is fitted with a flash memory device 1210 according to some embodiments of the inventive subject matter. The memory card 1200 according to some embodiments of the inventive subject matter includes a memory controller 1220 controlling every data exchange between a host and the flash memory device 1210.

A static random access memory (SRAM) 1221 is used as an operation memory of a processing unit 1222. A host interface 1223 includes data exchange protocols of a host to be connected to the memory card 1200. An error correction block 1224 detects and corrects errors included in data readout from a multi bit flash memory device 1210. A memory interface 1225 interfaces with the flash memory device 1210 of some embodiments of the inventive subject matter. The processing unit 1222 performs every control operation for exchanging data of the memory controller 1220. Though not depicted in drawings, it will be apparent to one of ordinary skill in the art that the memory card 1200 according to some embodiments of the inventive subject matter can further include a ROM (not shown) storing code data for interfacing with the host.

FIG. 12 is a block diagram illustrating an example of an information processing system including a semiconductor memory device according to some embodiments of the inventive subject matter.

Referring to FIG. 12, a flash memory system 1310 is built in a data processing system such as a mobile product or a desk top computer. The data processing system 1300 according to the inventive subject matter includes the flash memory system 1310 and a modem 1320, a central processing unit 1330, a RAM, a user interface 1350 that are electrically connected to a system bus 1360. The flash memory system 1310 may be constructed so as to be identical to the memory system or the flash memory system described above. The flash memory system 1310 stores data processed by the central processing unit 1330 or data inputted from an external device. The flash memory system 1310 may include a SSD (solid state disk) and in this case, the data processing system 1310 can stably store huge amounts of data in the flash memory system 1310. As reliability is improved, the flash memory system 1310 can reduce resources used to correct errors, thereby providing a high speed data exchange function to the data processing system 1300. Even though not depicted in the drawings, it is apparent to one of ordinary skill in the art that the data processing unit 1300 according to some embodiments of the inventive subject matter can further include an application chipset, a camera image processor (CIS) and/or an input/output device.

Flash memory devices or memory systems utilizing the inventive concepts can be mounted using any of various types of packages. For example, a flash memory device or a memory system according to the inventive subject matter can be packaged with methods such as PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multichip package (MCP), wafer-level fabricated package (WFP), wafer-level processed stack package (WSP) and mounted.

According to embodiments of the inventive concepts, a cell structure including vertically stacked conductive patterns may be formed using at least two individual processes, which are performed after forming a peripheral structure. For example, a lower layered structure may be formed after forming the peripheral structure, and then the lower layered structure may be patterned to form a lower portion of the cell structure (i.e., a lower cell structure). An upper layered structure may then be formed on the lower cell structure and the peripheral structure, and then the upper layered structure may then be patterned to form an upper portion of the cell structure (i.e., an upper cell structure).

As a result, technical difficulties, which may occur during patterning the cell structure, can be suppressed. For example, problems related to non-open holes or openings and damage to other elements can be reduced by adopting the inventive concepts.

While example embodiments have been particularly shown and described, it will be understood by one of ordinary skill in the art that variations in form and detail may be made therein without departing from the spirit and scope of the claims.

1. A method of fabricating a three-dimensional semiconductor memory device, comprising:
providing a substrate comprising a cell array region and a peripheral region;
forming a peripheral structure on the peripheral region of the substrate, the peripheral structure comprising peripheral circuits and configured to expose the cell array region of the substrate;
forming a lower cell structure on the cell array region of the substrate;
forming an insulating layer to cover the peripheral structure and the lower cell structure on the substrate;
planarizing the insulating layer using top surfaces of the peripheral structure and the lower cell structure as a planarization stop layer; and
forming an upper cell structure on the lower cell structure.

2. The method of claim 1, wherein the lower cell structure comprises first and second layers stacked alternately and repeatedly, and
the lower cell structure has substantially the same vertical thickness as the peripheral structure.

3. The method of claim 1, wherein the forming of the peripheral structure comprises:
forming the peripheral circuits on the peripheral region of the substrate; and
forming a peripheral insulating layer covering the peripheral circuits and exposing the cell array region of the substrate.

4. The method of claim 3, wherein the forming of the peripheral structure further comprises forming a peripheral sacrificial layer on a top surface of the peripheral insulating layer.

5. The method of claim 1, wherein the forming of the lower cell structure comprises:
alternately and repeatedly depositing first and second layers on the substrate having the peripheral structure to form a lower layered structure; and
removing the lower layered structure on the peripheral structure to form the lower cell structure.

6. The method of claim 5, wherein the forming of the lower cell structure further comprises forming a cell sacrificial layer on a top surface of the lower layered structure.

7. The method of claim 5, wherein the forming of the lower cell structure comprises patterning the lower layered structure plural times to sequentially expose top surfaces of the first layers between the cell array region and the peripheral region, and forming a spacer on a sidewall of the peripheral structure adjacent to the cell array region, the spacer being a portion of the lower layered structure remaining after the patterning of the lower layered structure.

8. The method of claim 5, wherein the peripheral circuits comprises a gate conductive pattern formed on the substrate, and wherein each of the first and second layers of the lower cell structure has a smaller vertical thickness than the gate conductive pattern of the peripheral circuits.

9. The method of claim 1, wherein the forming of the upper cell structure comprises:
alternately and repeatedly depositing first and second layers on the peripheral structure, the lower cell structure, and the planarized insulating layer, to form an upper layered structure; and
removing the upper layered structure on the peripheral structure to form the upper cell structure.

10. The method of claim 9, wherein the lower cell structure is formed to have a vertical thickness that is smaller than or equal to a vertical thickness of the upper cell structure.

11. The method of claim 1, further comprising conformally forming a planarization stop layer on the substrate having the peripheral structure and the lower cell structure before the forming of the insulating layer.

12. The method of claim 1, further comprising forming semiconductor patterns on the cell array region, each of the semiconductor patterns formed through the lower and upper cell structures and connected to the substrate.

13. The method of claim 12, after the forming of the semiconductor patterns, further comprising:
removing the first layers to form recess regions between the second layers; and
forming conductive patterns in the recess regions.

14. The method of claim 13, further comprising forming a data storage layer between the semiconductor pattern and the conductive pattern.

15. A method of fabricating a three-dimensional (3D) semiconductor memory device, comprising:
forming a peripheral circuit structure on a peripheral circuit region of a substrate; and
forming a 3D memory cell array on a cell array region of the substrate; and
forming an interconnection structure between the 3D memory cell array and the peripheral circuit structure,
wherein forming the 3D memory cell array comprises:
forming a lower cell structure on the cell array region of the substrate, the lower cell structure spaced from the peripheral circuit structure;
forming an insulating layer to cover the substrate, the peripheral structure and the lower cell structure;
planarizing the insulating layer using top surfaces of the peripheral circuit structure and the lower cell structure as a planarization stop layer such that a portion of the insulating layer remains on the substrate between the lower cell structure and the peripheral circuit structure; and
forming an upper cell structure on the lower cell structure.

16. The method of claim 15, wherein the forming of the upper cell structure comprises:
alternately and repeatedly depositing first and second layers on the peripheral structure, the lower cell structure, and the portion of the insulating layer, to form an upper layered structure; and
removing the upper layered structure from over the peripheral structure to form the upper cell structure.

17. The method of claim 15, wherein the forming of the upper cell structure comprises:
alternately and repeatedly depositing first and second layers on the peripheral structure, the lower cell structure, and the portion of the insulating layer, to form an upper layered structure; and
removing the upper layered structure from over the peripheral structure and the portion of the insulating layer to form the upper cell structure.

18. The method of claim 15, wherein the lower cell structure has substantially the same vertical thickness as the peripheral structure

19. The method of claim 15, wherein the 3D memory cell array is a flash memory cell array, wherein the lower cell structure includes a ground select line, a common source line and at least one word line of the flash memory cell array, and the upper cell structure includes at least one other word line of the flash memory cell array.

20. (canceled)
